(19) United States
(12) Patent Application Publication
(10) Pub. No.: US 2015/0085455 A1
(43) Pub. Date: Mar. 26, 2015

(54) ELECTRONIC COMPONENT-EMBEDDED SUBSTRATE AND MANUFACTURING METHOD THEREOF

(71) Applicant: SAMSUNG ELECTRO-MECHANICS CO., LTD., Gyeonggi-Do (KR)

(72) Inventors: Hong Won KIM, Suwon-si (KR); Kyoung Ro YOON, Daejeon-si (KR); Bong Soo KIM, Yeongi-gun (KR); Jung Soo BYUN, Anyang-si (KR); Kyo Min JUNG, Daejeon-si (KR); Tae Gon LEE, Daejeon-si (KR)

(73) Assignee: SAMSUNG ELECTRO-MECHANICS CO., LTD., Gyeonggi-Do (KR)

(21) Appl. No.: 14/496,750

(22) Filed: Sep. 25, 2014

(30) Foreign Application Priority Data
Sep. 26, 2013 (KR) 10-2013-0114436

(51) Int. Cl. H05K 1/18; H05K 3/32; H05K 1/11

(52) U.S. Cl. CPC H05K 1/186; H05K 1/115; H05K 3/32
USPC 361/761; 29/841

(57) ABSTRACT

Embodiments of the invention provide an electronic component-embedded substrate and a manufacturing method thereof. According to at least one embodiment, the electronic component-embedded substrate includes a cavity formed in a core substrate and including two or more embedding spaces which have a rectangular shape (when viewed on a plane) and are connected to each other by a connecting space, and two or more electronic components separately accommodated in the embedding spaces of the cavity, respectively. According to at least one embodiment, neighboring long sides of first and second embedding spaces are partially connected to each other by the connecting space, and one side (when viewed on the plane) forming a connecting width of the connecting space connecting the first and second embedding spaces to each other coincides with one short side of the first embedding space, and the other side (when viewed on the plane) coincides with the other short side of the second embedding space.

### CROSS REFERENCE TO RELATED APPLICATION

This application claims the benefit of and priority under 35 U.S.C. §119 to Korean Patent Application No. KR 10-2013-0114436, entitled “ELECTRONIC COMPONENT-EMBEDDED SUBSTRATE AND MANUFACTURING METHOD THEREOF,” filed on Sep. 26, 2013, which is hereby incorporated by reference in its entirety into this application.

### BACKGROUND

1. Field of the Invention

Embodiments of he invention relate to an electronic component-embedded substrate and a manufacturing method thereof. More particularly, embodiments of the invention relates to an electronic component-embedded substrate having an improved cavity structure in which two or more embedding spaces having electronic components inserted thereinto, respectively, and a connecting space connecting the embedding spaces to each other are provided in one cavity, and a manufacturing method thereof.

2. Description of the Related Art

In accordance with the development of an electronic industry, a demand for multi-functionalization and miniaturization of electronic components has gradually increased. As a result, a circuit board has become slim and light. In accordance with multi-functionalization and densification of an electronic device, a size of a substrate has decreased, while the number of embedded components has increased. As an effort to provide more functions in a limited area of the substrate, the development of an electronic component-embedded substrate has been actively conducted.

A scheme of embedding electronic components according to the related art will be described. Cavities in which electronic components are to be mounted are formed in a core substrate, and the electronic components are embedded in the cavities. A build-up layer is formed so as to cover the cavities, and vias are formed in the build-up layer and are electrically connected to electrodes or pads of the electronic component to form the electronic component-embedded substrate.

In order to improve a degree of freedom in a design by minimizing an area of the cavities occupied by the embedded components at the time of manufacturing the electronic component-embedded substrate, a scheme of embedding a plurality of electronic components in one large cavity has been suggested instead of a scheme of forming independent cavities with respect to the respective embedded components.

In this scheme, the electronic component-embedded substrate is manufactured by embedding the plurality of electronic components in one cavity and then stacking an insulating material, for example, a resin. However, the resin flows in a margin space in the cavity at the time of being stacked, such that the embedded components inserted into the cavity are also shifted by the resin.

The shift of the embedded components may cause a short-circuit between the plurality of embedded components inserted into one cavity and/or may cause, for example, an eccentricity defect of the via.

### SUMMARY

Accordingly, embodiments of the invention have been made to provide a technology for improving a cavity structure so as to limit a shift range of a plurality of electronic components in the case in which the plurality of electronic components are inserted into one cavity.

According to at least one embodiment, there is provided an electronic component-embedded substrate including a cavity formed in a core substrate and including two or more embedding spaces which have a rectangular shape (when viewed on a plane) and are connected to each other by a connecting space, and two or more electronic components separately accommodated in the embedding spaces of the cavity, respectively. According to at least one embodiment, neighboring long sides of first and second embedding spaces connected to each other by the connecting space are partially connected to each other by the connecting space, and one side (when viewed on the plane) forming a connecting width of the connecting space connecting the first and second embedding spaces to each other coincides with one short side of the first embedding space, and the other side (when viewed on the plane) coincides with the other short side of the second embedding space.

According to at least one embodiment, the connecting width w of the connecting space satisfies the following Equation:

$$a sin {θ}_{i} < w \leq \frac{ab}{a + Δ} .$$

A According to at least one embodiment, a is a length of a short side (when viewed on the plane) of the electronic component, b is a length of a long side (when viewed on the plane) of the electronic component, Δ is a difference between a length of a short side of the embedding space and a length of the short side of the electronic component, and θᵢ is a maximum rotatable angle in an independent cavity that does not have the connecting space and has a length of a short side (when viewed on the plane) corresponding to a+Δ.

According to at least one embodiment, Δ satisfies the following Equation: 0<Δ<b−a, and a height h of the connecting space (when viewed on the plane), which is a distance between the long side of the first embedding space and the long side of the second embedding space neighboring to the first embedding space, satisfies the following Equation: h≦a+Δ.

According to at least one embodiment, the height h of the connecting space (when viewed on the plane) satisfies the following Equation: b sin θₘₐₓ+a cos θₘₐₓ−(a+Δ)<h, where θₘₐₓ is a maximum rotatable angle of the electronic component accommodated in the embedding space.

According to at least one embodiment, a maximum rotatable angle θₘₐₓ of the electronic component accommodated in the embedding space in a condition of the following Equation 1:

$$0 < Δ \leq \sqrt{\frac{{b}^{2} + b \sqrt{{b}^{2} - 4 {a}^{2}}}{2}} - a$$

and b>2a satisfies the following Equation:

$${sin}^{- 1} \frac{a + Δ}{\sqrt{{a}^{2} + {b}^{2}}} - {cos}^{- 1} \frac{b}{\sqrt{{a}^{2} + {b}^{2}}} < {θ}_{max} \leq {sin}^{- 1} \frac{a + Δ}{b} .$$

According to at least one embodiment, a maximum rotatable angle θₘₐₓ of the electronic component in a condition in which b>2a and Equation 1 is not satisfied or b≦2a satisfies the following Equation:

$${sin}^{- 1} \frac{a + Δ}{\sqrt{{a}^{2} + {b}^{2}}} - {cos}^{- 1} \frac{b}{\sqrt{{a}^{2} + {b}^{2}}} < {θ}_{ma x} \leq {cos}^{- 1} \frac{a}{a + Δ} .$$

### Here,

$${sin}^{- 1} \frac{a + Δ}{b} and {cos}^{- 1} \frac{a}{a + Δ}$$

is a maximum rotatable angle θₘₐₓ_{_{—}}_{wmax} of the electronic component in the case in which

$${w}_{ma x} = \frac{ab}{a + Δ} ,$$

wₘₐₓ is a maximum connecting width of the connecting space for any Δ, and

$${sin}^{- 1} \frac{a + Δ}{\sqrt{{a}^{2} + {b}^{2}}} - {cos}^{- 1} \frac{b}{\sqrt{{a}^{2} + {b}^{2}}}$$

is a maximum rotatable angle in the independent cavity that does not have the connecting space and has the length of the short side (when viewed on the plane) corresponding to a+Δ.

According to at least one embodiment, the height h of the connecting space (when viewed on the plane) satisfies the following Equation: w tan θₘₐₓ≦h≦a+Δ in a condition in which the maximum rotatable angle θₘₐₓ of the electronic component accommodated in the embedding space satisfies the following Equation:

$${θ}_{ma x} \leq \frac{π}{4} ,$$

and the height h of the connecting space (when viewed on the plane) satisfies the following Equation:

$$\frac{w}{tan {θ}_{ma x }} \leq h \leq a + Δ$$

in a condition in which the maximum rotatable angle θₘₐₓ of the electronic component satisfies the following Equation:

$${θ}_{m ax} \geq \frac{π}{4} .$$

According to at least one embodiment, the height h of the connecting space (when viewed on the plane) satisfies the following Equation:

$$h \leq 2 ( b sin {θ}_{m ax} + a cos {θ}_{ma x} - ( a + Δ ) ) . \\ \frac{b}{2} \leq w , and Δ \leq ( \sqrt{2} - 1 ) a .$$

According to at least one embodiment, one end portion of at least one side forming the connecting width of the connecting space is connected to a short side of any one of first and second embedding spaces so as to coincide therewith, and the other end portion thereof is bent and meet a long side of the other embedding space, w, which is a long width of the connecting space formed by a distal end of the other end portion, is larger than a short width of the connecting space formed by a bent point of the other end portion, and a maximum rotation angle is formed at a distal end of the other end portion at the time of maximum rotation of the electronic component accommodated in the embedding space.

According to at least one other embodiment, there is provided an electronic component-embedded substrate including a core substrate, a cavity formed in the core substrate and including a first embedding space, which is one of two or more embedding spaces and is formed in a horizontal rectangular shape (when viewed on a plane), a connecting space, which is connected to a portion of a lower long side of the first embedding space, of which one side (when viewed on the plane) forming a connecting width coincides with one short side of the first embedding space and the other side (when viewed on the plane) meets the lower long side of the first embedding space, and a second embedding space, which is formed in a horizontal rectangular shape (when viewed on the plane) and has the other short side coinciding with the other side (when viewed on the plane) of the connecting space and an upper long side meeting the one side (when viewed on the plane) of the connecting space, two or more electronic components maximally rotatable at a point at which a side of the connecting space and a long side of the embedding space meet each other and separately accommodated in the embedding spaces of the cavity, respectively, so as not to contact each other at the time of being maximally rotated, and upper and lower insulating layers covering the electronic components embedded in the cavity and having a plurality of vias formed therein so as to be electrically connected to the electronic components while penetrating through at least one thereof.

According to at least one embodiment, the connecting width w of the connecting space satisfies the following Equation:

$$a sin {θ}_{i} < w \leq \frac{ab}{a + Δ} .$$

According to at least one embodiment, a is a length of a short side (when viewed on the plane) of the electronic component, b is a length of a long side (when viewed on the plane) of the electronic component, Δ is a difference between a length of a short side of the embedding space and a length of the short side of the electronic component, and θᵢ is a maximum rotatable angle in an independent cavity that does not have the connecting space and has a length of a short side (when viewed on the plane) corresponding to a+Δ.

According to at least one embodiment, Δ satisfies the following Equation: 0<Δ<b−a, and a height h of the connecting space (when viewed on the plane), which is a distance between the long side of the first embedding space and the long side of the second embedding space, satisfies the following Equation: h≦a+Δ.

According to at least one embodiment, the height h of the connecting space (when viewed on the plane) satisfies the following Equation: b sin θₘₐₓ+a cos θₘₐₓ−(a+Δ)<h, where θₘₐₓ is a maximum rotatable angle of the electronic component accommodated in the embedding space.

$$\frac{b}{2} \leq w and Δ \leq ( \sqrt{2} - 1 ) a .$$

According to still at least one other embodiment, there is provided a manufacturing method of an electronic component-embedded substrate, including forming a cavity, in a core substrate, configured that two or more embedding spaces having a rectangular shape (when viewed on a plane) are connected to each other by a connecting space, so that neighboring long sides of first and second embedding spaces are partially connected to each other by the connecting space and one side (when viewed on the plane) forming a connecting width of the connecting space connecting the first and second embedding spaces coincides with one short side of the first embedding space, and the other side (when viewed on the plane) coincides with the other short side of the second embedding space, separately inserting two or more electronic components into the embedding spaces of the cavity, respectively, and covering the cavity into which the electronic components are inserted with an insulating layer(s) and forming a plurality of vias electrically connected to the electronic components while penetrating through the insulating layer.

According to at least one embodiment, in the forming of the cavity, the cavity is formed, so that the connecting width w of the connecting space satisfies the following Equation:

$$a sin {θ}_{i} < w \leq \frac{ab}{a + Δ} .$$

According to at least one embodiment, a is a length of a short side (when viewed on the plane) of the electronic component, b is a length of a long side (when viewed on the plane) of the electronic component, Δ is a difference between a length of a short side of the embedding space and a length of the short side of the electronic component, and θᵢ is a maximum rotatable angle in an independent cavity that does not have the connecting space and has a length of a short side (when viewed on the plane) corresponding to a+Δ.

According to at least one embodiment, in the forming of the cavity, the cavity is formed, so that Δ satisfies the following Equation: 0<Δ<b−a, and a height h of the connecting space (when viewed on the plane), which is a distance between the long side of the first embedding space and the long side of the second embedding space, satisfies the following Equation: h≦a+Δ.

According to at least one embodiment, in the forming of the cavity, the cavity is formed, so that a maximum rotatable angle θₘₐₓ of the electronic component accommodated in the embedding space in a condition of the following Equation 1:

$$0 < Δ < \sqrt{\frac{{b}^{2} + b \sqrt{{b}^{2} - 4 {a}^{2}}}{2}} - a$$

and b>2a satisfies the following Equation:

$${sin}^{- 1} \frac{a + Δ}{\sqrt{{a}^{2} + {b}^{2}}} - {cos}^{- 1} \frac{b}{\sqrt{{a}^{2} + {b}^{2}}} < {θ}_{m ax} \leq {sin}^{- 1} \frac{a + Δ}{b} .$$

According to at least one embodiment, in the forming of the cavity, the cavity is formed, so that a maximum rotatable angle θₘₐₓ of the electronic component in a condition in which Equation 1 is not satisfied or b≦2a satisfies the following Equation:

$${sin}^{- 1} \frac{a + Δ}{\sqrt{{a}^{2} + {b}^{2}}} - {cos}^{- 1} \frac{b}{\sqrt{{a}^{2} + {b}^{2}}} < {θ}_{m ax} \leq {cos}^{- 1} \frac{a}{a + Δ} .$$

### Here,

$${sin}^{- 1} \frac{a + Δ}{b} and {cos}^{- 1} \frac{a}{a + Δ}$$

is a maximum rotatable angle θₘₐₓ_{_{—}}_{wmax} of the electronic component in the case in which

$${w}_{max} = \frac{ab}{a + Δ} ,$$

wₘₐₓ is a maximum connecting width of the connecting space for any Δ, and

$${sin}^{- 1} \frac{a + Δ}{\sqrt{{a}^{2} + {b}^{2}}} - {cos}^{- 1} \frac{b}{\sqrt{{a}^{2} + {b}^{2}}}$$

is a maximum rotatable angle in the independent cavity that does not have the connecting space and has the length of the short side (when viewed on the plane) corresponding to a+Δ.

According to at least one embodiment, in the forming of the cavity, the cavity is formed, so that the height h of the connecting space (when viewed on the plane) satisfies the following Equation: b sin θₘₐₓ+a cos θₘₐₓ−(a+Δ)<h.

According to at least one embodiment, in the forming of the cavity, the cavity is formed, so that

$$\frac{b}{2} \leq w and Δ \leq ( \sqrt{2} - 1 ) a .$$

Various objects, advantages and features of the invention will become apparent from the following description of embodiments with reference to the accompanying drawings.

### BRIEF DESCRIPTION OF DRAWINGS

These and other features, aspects, and advantages of the invention are better understood with regard to the following Detailed Description, appended Claims, and accompanying Figures. It is to be noted, however, that the Figures illustrate only various embodiments of the invention and are therefore not to be considered limiting of the invention's scope as it may include other effective embodiments as well.

FIG. 1 is a plan view schematically showing an electronic component-embedded substrate according to an embodiment of the invention.

FIGS. 2A to 2C are plan views schematically showing an electronic component-embedded substrate according to another embodiment of the invention.

FIGS. 3A to 3D are plan views schematically showing an electronic component-embedded substrate according to another embodiment of the invention.

FIG. 4 is a plan view partially showing an electronic component-embedded substrate according to another embodiment of the invention.

FIG. 5 is a cross-sectional view schematically showing an electronic component-embedded substrate according to another embodiment of the invention.

FIG. 6 is a flow chart schematically showing a manufacturing method of an electronic component-embedded substrate according to another embodiment of the invention.

### DETAILED DESCRIPTION

Advantages and features of the invention and methods of accomplishing the same will be apparent by referring to embodiments described below in detail in connection with the accompanying drawings. However, the invention is not limited to the embodiments disclosed below and may be implemented in various different forms. The embodiments are provided only for completing the disclosure of the invention and for fully representing the scope of the invention to those skilled in the art.

For simplicity and clarity of illustration, the drawing figures illustrate the general manner of construction, and descriptions and details of well-known features and techniques may be omitted to avoid unnecessarily obscuring the discussion of the described embodiments of the invention. Additionally, elements in the drawing figures are not necessarily drawn to scale. According to at least one embodiment, the dimensions of some of the elements in the figures may be exaggerated relative to other elements to help improve understanding of embodiments of the invention. Like reference numerals refer to like elements throughout the specification.

Hereinafter, various embodiments of the invention will be described in detail with reference to the accompanying drawings.

Electronic Component-Embedded Substrate

First, an electronic component-embedded substrate according to an embodiment of the invention will be described in detail with reference to the accompanying drawings. In the specification, the same reference numerals will be used in order to describe the same components throughout the accompanying drawings.

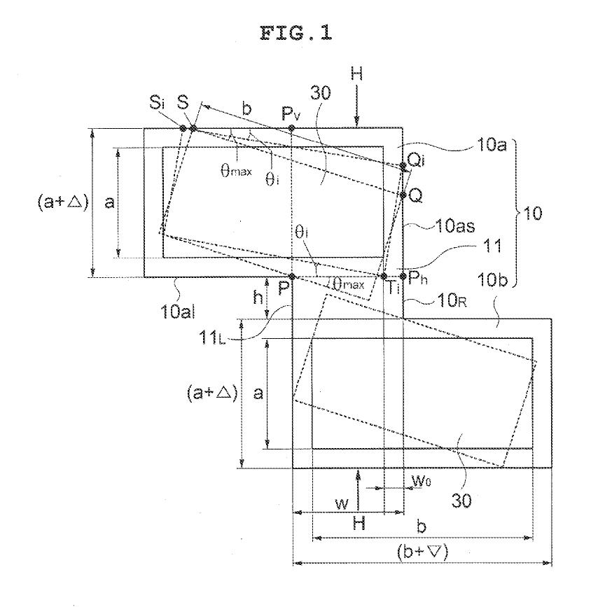

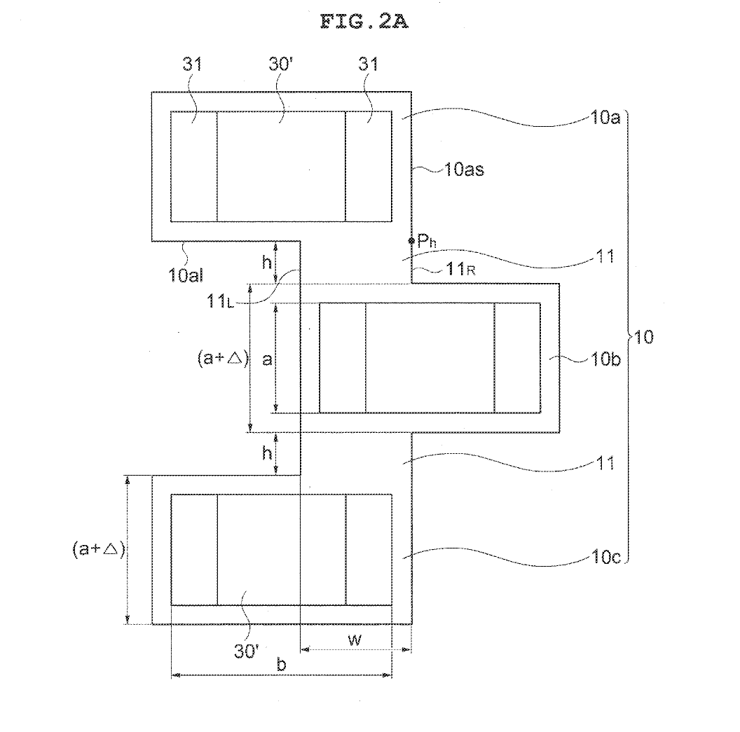

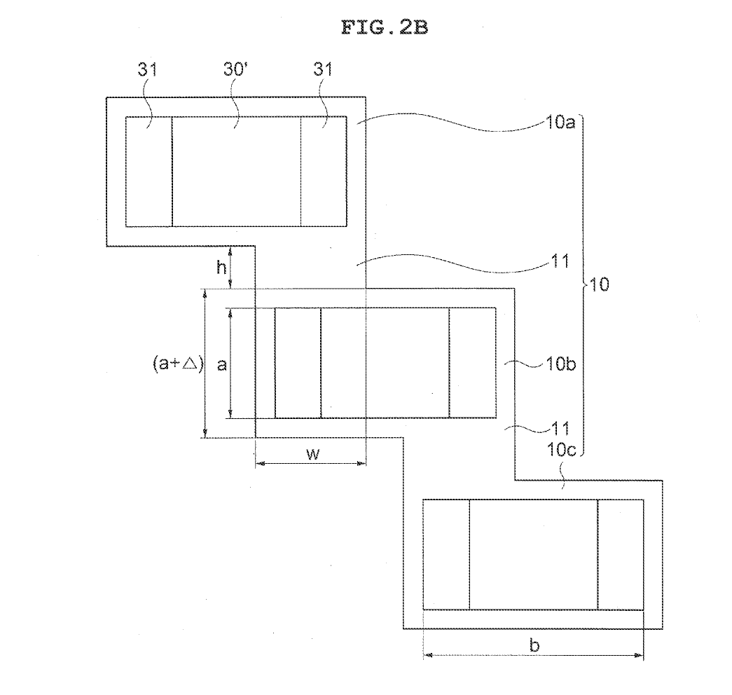

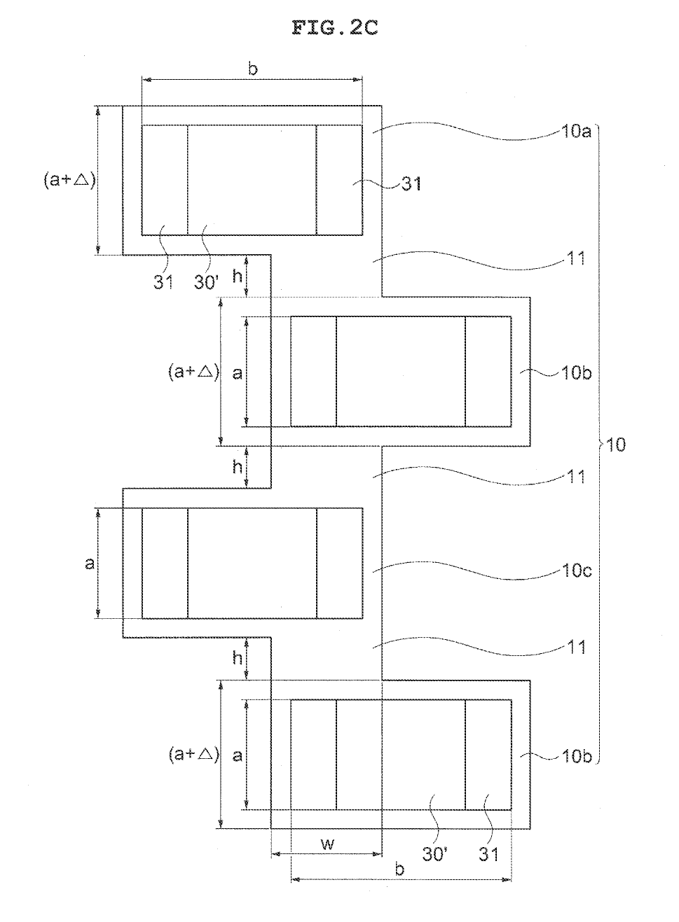

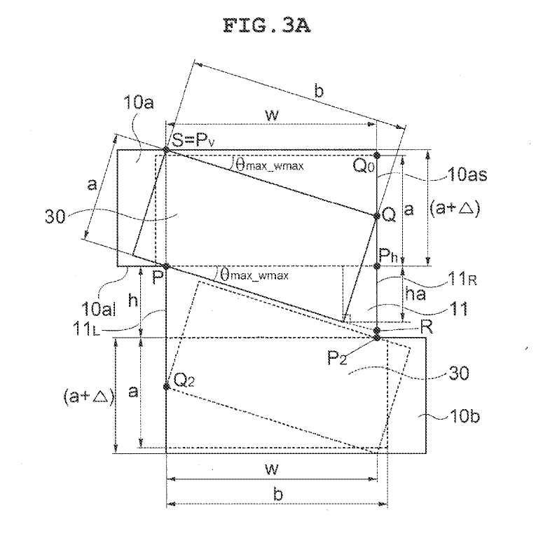

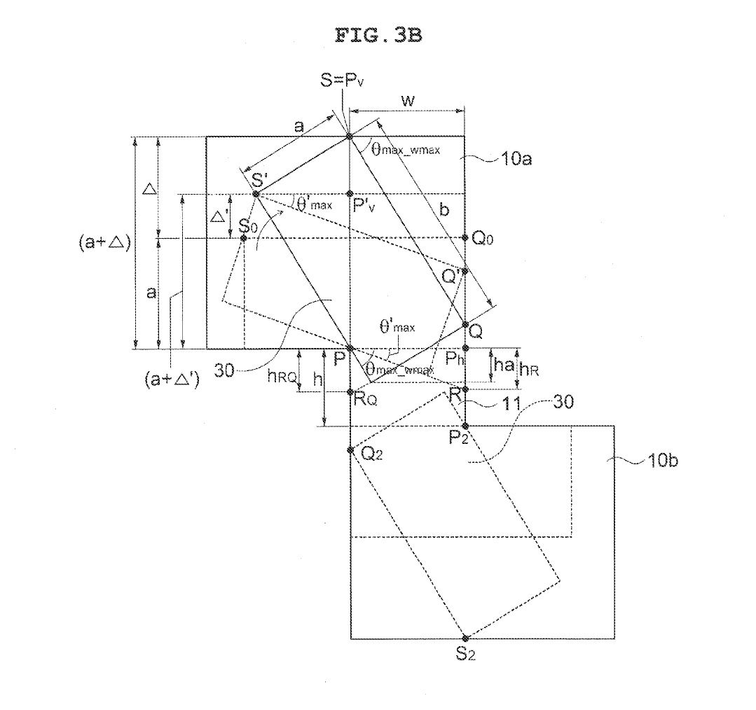

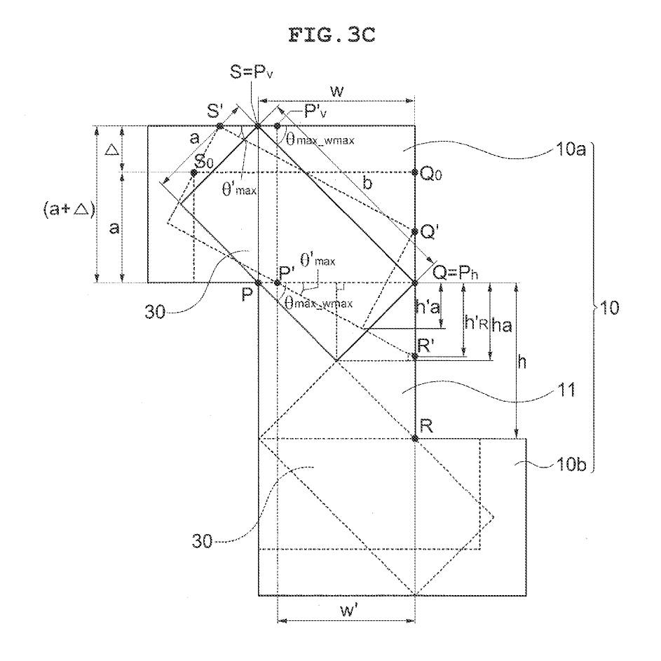

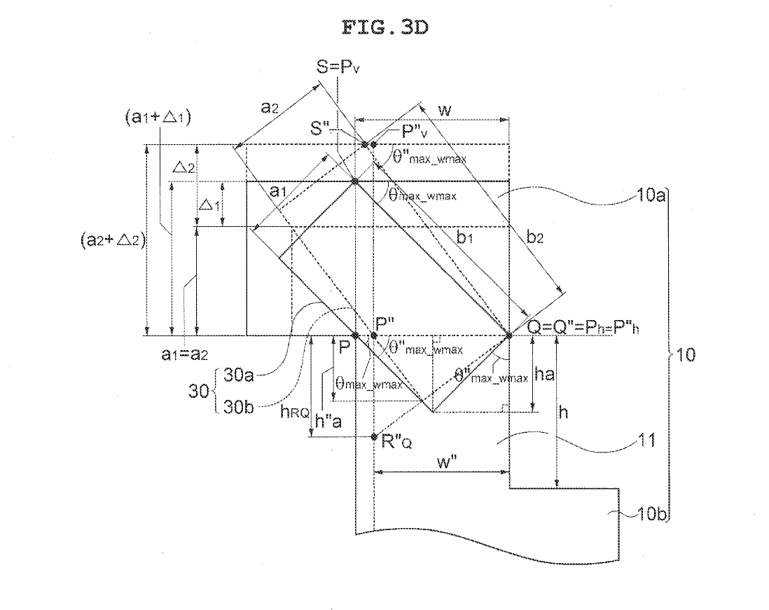

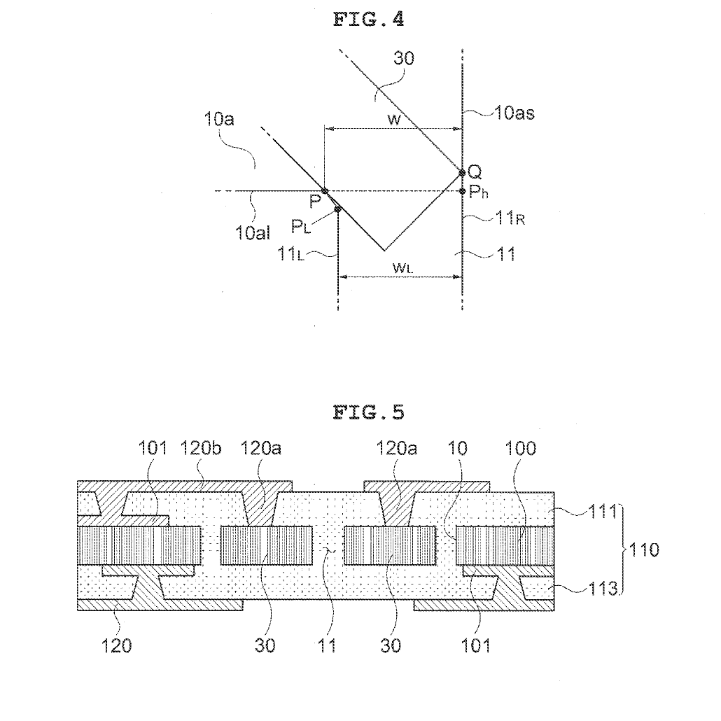

FIG. 1 is a plan view schematically showing an electronic component-embedded substrate according to an embodiment of the invention; FIGS. 2A to 2C are plan views schematically showing an electronic component-embedded substrate according to another embodiment of the invention; FIGS. 3A to 3D are plan views schematically showing an electronic component-embedded substrate according to another embodiment of the invention; FIG. 4 is a plan view partially showing an electronic component-embedded substrate according to another embodiment of the invention; and FIG. 5 is a cross-sectional view schematically showing an electronic component-embedded substrate according to yet still according to another embodiment of the invention.

Referring to FIGS. 1 to 5, an electronic component-embedded substrate according to another embodiment of the invention is configured to include a cavity 10 and two or more electronic components 30 and 30′. The respective components will be described in detail with reference to FIGS. 1 to 5.

First, referring to FIGS. 1 to 5, the cavity 10 of the electronic component-embedded substrate is formed in a core substrate 100. According to at least one embodiment, the cavity 10 includes two or more embedding spaces 10a and 10b having a rectangular shape when viewed on a plane |[A1] and connected to each other by a connecting space 11. According to at least one embodiment, first and second embedding spaces 10a and 10b are connected to each other by the connecting space 11. According to at least one embodiment, neighboring long sides of the first and second embedding spaces 10a and 10b connected to each other by the connecting space 11 are partially connected to each other. According to at least one embodiment, the first and second embedding spaces 10a and 10b are only partially connected to each other.

According to at least one embodiment, one side 11_{R} (when viewed on the plane) forming a connecting width of the connecting space 11 connecting the first and second embedding spaces 10a and 10b to each other coincides with one short side 10as of the first embedding space 10a, and the other side 11_{L} (when viewed on the plane) coincides with the other short side of the second embedding space 10b. Thus, one side 11_{R} of the connecting width of the connecting space 11 coincides with one short side 10as of the first embedding space 10a and meets a long side of the second embedding space 10b. In addition, the other side 11L of the connecting width of the connecting space 11 coincides with the other short side of the second embedding space 10b and meets a long side 10al of the first embedding space 10a.

According to at least one embodiment, the cavity includes the two or more embedding spaces 10a and 10b and the connecting space 11 connecting the embedding spaces 10a and 10b to each other, thereby making it possible to minimize a short-circuit due to a contact between the electronic components 30 inserted in the embedding spaces 10a and 10b, respectively. Therefore, according to at least one embodiment, the short-circuit is structurally prevented. Thus, in at least one embodiment, even though a shift occurs in the electronic components 30 inserted into the embedding spaces 10a and 10b at the time of stacking an insulating layer, for example, the short-circuit between the embedded electronic components 30 is prevented. In addition, in the present exemplary embodiment, the shift of the electronic components 30 is minimized by a structure of the embedding spaces 10a and 10b and the connecting space 11. Therefore, an eccentricity defect of a via 120a is prevented.

Further, according to at least one embodiment, a margin volume is decreased in the case in which an insulating material is filled in the margin of the cavity 10 into which the electronic components 30 are inserted according to stacking of the insulating layer 110 than in the case in which two or more electronic components 30 are embedded in the cavity 10 having a rectangular shape according to the conventional art and/or the electronic components 30 are embedded in independent cavities, respectively, according to the conventional art. Therefore, a stacking void occurring due to insufficient of the insulating material filled in the margin volume, for example, is improved. Further, according to at least one embodiment, the insulating material is sufficiently filled in the margin volume, thereby making it possible to accomplish an improvement effect for a delamination problem between the electronic component 30 and the insulating material.

According to at least one embodiment, the two or more electronic components 30 of the electronic component-embedded substrate are separately accommodated in the embedding spaces 10a and 10b of the cavity 10, respectively, and do not directly contact each other.

According to at least one embodiment, according to at least one embodiment, a connecting width w of the connecting space 11 satisfies the following Equation:

$$a sin {θ}_{i} < w \leq \frac{ab}{a + Δ} .$$

According to at least one embodiment, a is a length of a short side (when viewed on the plane) of the electronic component 30, and b is a length of a long side (when viewed on the plane) of the electronic component 30. Thus, the electronic components 30 satisfying the following Equation: a<b are embedded in the embedding spaces 10a and 10b, respectively. Here, Δ is a difference between a length of a short side of the embedding space 10a or 10b and a length of a short side of the electronic component 30. Thus, in the case in which the length b of the long side of the electronic component 30 and the length a of the short side of the electronic component 30 are determined, a range of the connecting width w of the connecting space 11 is determined by a margin of the short side of the embedding space 10a or 10b rather than a margin of the long side thereof.

According to at least one embodiment, the connecting space 11 is added, such that the connecting width of the connecting space 11 exceeds a predetermined range in order to increase a rotatable angle of the electronic component 30. Thus, the connecting width should be larger than a length between points Tᵢ and Pₕ, which are an opposite side to a rotatable maximum angle <Qᵢ in a triangle formed by a rotatable maximum angle in an independent cavity that does not have the connecting space 11, for example, a triangle formed of points Qᵢ, Tᵢ, Pₕ in FIG. 1. Therefore, referring to the electronic component 30 shown as the dotted line rectangle including vertexes Sᵢ, Qᵢ, and Tᵢ of FIG. 1, the connecting width w of the connecting space 11 satisfies the following Equation: a sin θᵢ<w. According to at least one embodiment, θᵢ is a maximum rotatable angle in an independent cavity that does not have the connecting space 11 and has a length of a short side (when viewed on the plane) corresponding to a+Δ.

Referring to FIGS. 1 and 3A to 3D, the electronic component 30 is maximally rotated at a point P at which a lower long side 10al of the embedding space 10a and the other side 11_{L} forming the connecting width of the connecting space 11 meet each other. According to at least one embodiment, a maximum rotation range is changed depending on a change in a difference Δ between a margin of the short side of the embedding space 10a, thus, the length of the short side of the embedding space 10a and a length of the short side of the electronic component 30. According to at least one embodiment, a distance between the point P, which is a rotation origin point, and a point Pₕ on one short side of the embedding space 10a that a horizontal extension line of the point P meets is the connecting width w of the connecting space 11. In addition, here, a maximum value of the connecting width w of the connecting space 11 is changed depending on Δ. Thus, the larger Δ, the larger the maximum rotatable angle at the point P and the larger the maximum value of the connecting width w of the connecting space 11. According to at least one embodiment, the maximum value of the connecting width w of the connecting space 11 means a connecting width w at which the electronic component 30 inserted into the embedding space 10a or 10b is rotated at a maximum rotation angle at the point P without getting out to the connecting space 11. Thus, in the maximum value of the connecting width w of the connecting space 11, a maximum rising vertex S of two upper vertexes of the electronic component 30 coincides with a point Pᵥ at which the extension line passing through the point P, which is the rotation origin point, and an upper long side of the embedding space 10a meet each other or an upper falling vertex Q or Q″ (See FIG. 3C or 3D), which is the other of the two upper vertexes of the electronic component 30 coincides with a point Pₕ. According to at least one embodiment, in the case in which the maximum rising vertex S of the electronic component 30 exceeds the point Pᵥ and then becomes close to one short side 10as of the embedding space 10a or the upper falling vertex of the electronic component 30 exceeds the point Pₕ and then becomes distant downwardly from the point Pₕ, the electronic component 30 gets out to the connecting space 11. Therefore, for any Δ, the connecting width w of the connecting space 11 is determined in a range in which the upper falling vertex of the electronic component 30 does not fall in excess of the point Pₕ and the maximum rising vertex of the electronic component 30 does not approach one short side 10as of the embedding space 10a in excess of the point Pᵥ along an upper long side of the embedding space 10a when the electronic component 30 in the embedding space 10a is maximally rotated around the rotation origin point P.

According to at least one embodiment, a maximum connecting width of the connecting space 11 for any Δ is

$$\frac{ab}{a + Δ} .$$

According to at least one embodiment, in FIGS. 3A to 3D, in the case in which the maximum rising vertex S of the electronic component 30 coincides with the point Pᵥ, a maximum connecting width wₘₐₓ of the connecting space 11 for any Δ or Δ₁ is calculated as follows. A connecting width w of the connecting space 11 shown in FIGS. 3A to 3D is the maximum connecting width wₘₐₓ. According to at least one embodiment, in FIGS. 3A and 3B, the upper falling vertex Q of the electronic component 30 does not arrive at the point Pₕ, unlike FIGS. 3C and 3D.

Since

$$cos {θ}_{max\_w max} = \frac{a}{a + Δ} = \frac{{w}_{max}}{b} or$$

$$cos {θ}_{max\_w max} = \frac{{a}_{1}}{{a}_{1} + {Δ}_{1}} = \frac{{w}_{max}}{{b}_{1}} , {w}_{max} = \frac{ab}{a + Δ} or$$

$${w}_{max} = \frac{{a}_{1} {b}_{1}}{{a}_{1} + {Δ}_{1}} .$$

Meanwhile, in FIG. 3C, a connecting width w′ of the connecting space 11 is any connecting width smaller than the maximum connecting width wₘₐₓ. In this case, a maximum rising vertex S′ of the electronic component 30 does not arrive at the point Pᵥ and the upper falling vertex Q′ of the electronic component 30 does not arrive at the point Pₕ.

According to at least one embodiment, in FIGS. 3C and/or 3D, in the case in which the upper falling vertex Q or Q2 of the electronic component 30 coincides with the point Pₕ, a maximum connecting width wₘₐₓ of the connecting space 11 for any Δ or Δ₂ is calculated as follows. Connecting widths w and w″ of the connecting space 11 shown in FIGS. 3C and 3D are the maximum connecting width wₘₐₓ. According to at least one embodiment, in FIG. 3D, a maximum rising vertex S″ of the electronic component 30 does not arrive the point Pᵥ, unlike FIG. 3C.

Since

$$sin {θ}_{max\_w max} = \frac{a}{{w}_{max}} = \frac{a + Δ}{b} or$$

$$sin {θ}_{max\_w max} = \frac{{a}_{2}}{{w}_{max}} = \frac{{a}_{2} + {Δ}_{2}}{{b}_{2}} , {w}_{max} = \frac{ab}{a + Δ} or$$

$${w}_{max} = \frac{{a}_{2} {b}_{2}}{{a}_{2} + {Δ}_{2}} .$$

According to at least one embodiment, θₘₐₓ_{_{—}}_{wmax} is a maximum rotatable angle of the electronic component 30 at the maximum connecting width wₘₐₓ of the connecting space 11 for any Δ. For reference, θₘₐₓ of FIG. 1 is a maximum rotatable angle of the electronic component 30 at the rotation origin point P at the connecting width w of the connecting space 11 for any Δ, and θ′ₘₐₓ of FIG. 3 is a maximum rotatable angle of the electronic component 30 at the rotation origin point P at a connecting width w′ of any connecting space 11 for any Δ. In addition, in FIG. 3D, a₁ and a₂ are a length of a short side of the electronic component 30, and b₁ and b₂ are a length of a long side of the electronic component 30. Here, a₁=a₂, and b₁≠b₂. Thus, FIG. 3D shows a connecting width of the connecting space 11 in the case in which a length of the long side of the electronic component 30 is changed.

Therefore, since the maximum connecting width of the connecting space 11 for any Δ is

$$\frac{ab}{a + Δ} ,$$

the connecting width w of the connecting space 11 for any Δ is

$$w \leq \frac{ab}{a + Δ} .$$

According to at least one embodiment, Δ satisfies the following Equation: 0<Δ<b−a. Here, a height h of the connecting space 11 (when viewed on the plane), which is a distance between a long side 10al of the first embedding space 10a and a long side of the second embedding space 10b neighboring to the first embedding space 10a, satisfies the following Equation: h≦a+Δ. Since the electronic components 30 is inserted into the embedding spaces 10a and 10b, a should be larger than 0. In addition, when Δ is equal to or larger than b−a, the long sides of the electronic components 30 is inserted into the short sides of the embedding spaces 10a and 10b. Therefore, Δ is smaller than b−a. Here, an entire size of the cavity 10 is set so that the height h of the connecting space 11 (when viewed on the plane) satisfies the following Equation: h≦a+Δ.

According to at least one embodiment, referring to FIGS. 3A to 3D, the height h of the connecting space 11 (when viewed on the plane) satisfies the following Equation: b sin θₘₐₓ+a cos θₘₐₓ−(a+Δ)<h. θₘₐₓ is a maximum rotatable angle of the electronic component 30 accommodated in the embedding space 10a or 10b. According to at least one embodiment, referring to FIGS. 3A to 3C, b sin θₘₐₓ_{_{—}}_{wmax}+a cos θₘₐₓ_{_{—}}_{wmax}=a+Δ+hₐ, referring to FIG. 3D, b₁ sin θₘₐₓ_{_{—}}_{wmax}+a₁ cos θₘₐₓ_{_{—}}_{wmax}=a₁+Δ₁+hₐ or b₂ sin θₘₐₓ_{_{—}}_{wmax}+a₂ cos θ″ₘₐₓ_{_{—}}_{wmax}=a₂+Δ₂+h″ₐ, and referring to FIG. 3C, b sin θ′ₘₐₓ+a cos θ′ₘₐₓ=a+Δ+h′ₐ. Thus, since hₐ=b sin θₘₐₓ_{_{—}}_{wmax}+a cos θₘₐₓ_{_{—}}_{wmax}−(a+Δ), hₐ=b₁ sin θₘₐₓ_{_{—}}_{wmax}+a₁ cos θₘₐₓ_{_{—}}_{wmax}−(a₁+Δ₁), h′ₐ=b sin θₘₐₓ+a cos θ′ₘₐₓ−(a+Δ), or h″ₐ=b₂ sin θₘₐₓ_{_{—}}_{wmax}+a₂ cos θ″ₘₐₓ_{_{—}}_{wmax}−(a₂+Δ₂), the height h of the connecting space 11 (when viewed on the plane) satisfies the following Equation: h>b sin θₘₐₓ+a cos θₘₐₓ−(a+Δ). According to at least one embodiment, θₘₐₓ_{_{—}}_{wmax} is a maximum rotatable angle of the electronic component 30 at the maximum connecting width wₘₐₓ of the connecting space 11 for any Δ, and θ′ₘₐₓ of FIG. 3C is a maximum rotatable angle of the electronic component 30 at an allowable connecting width w′ of the connecting space 11 for any Δ. In addition, hₐ is a height at which the electronic component 30 protrudes downwardly of the lower long side 10al of the embedding space 10a when the electronic component 30 is maximally rotated at the maximum connecting width wₘₐₓ, of the connecting space 11 for any Δ or Δ₁, h″ₐ is a height at which the electronic component 30 protrudes downwardly of the lower long side 10al of the embedding space 10a when the electronic component 30 is maximally rotated at the maximum connecting width wₘₐₓ of the connecting space 11 for any Δ₂, and h′ₐ is a height at which the electronic component 30 protrudes downwardly of the lower long side 10al of the embedding space 10a when the electronic component 30 is maximally rotated at the allowable connecting width w′ of the connecting space 11 for any Δ. Thus, each of hₐ, h′ₐ, and h″ₐ is a height from the lower long side 10al of the embedding space 10a to the maximum falling vertex of the electronic component 30 when the electronic component 30 inserted into the embedding space 10a is maximally rotated.

According to at least one embodiment, generally referring to FIGS. 1 and 3D, the maximum rotatable angle θₘₐₓ of the electronic component 30 accommodated in the embedding space 10a in a condition of the following Equation 1:

$$0 < Δ \leq \sqrt{\frac{{b}^{2} + b \sqrt{{b}^{2} - 4 {a}^{2}}}{2}} - a$$

and b>2a satisfies the following Equation:

$${sin}^{- 1} \frac{a + Δ}{\sqrt{{a}^{2} + {b}^{2}}} - {cos}^{- 1} \frac{b}{\sqrt{{a}^{2} + {b}^{2}}} < {θ}_{max} \leq {sin}^{- 1} \frac{a + Δ}{b} .$$

Referring to FIG. 1, when the electronic component is maximally rotated in the independent cavity that does not have the connecting space 11 and has the length of the short side (when viewed on the plane) corresponding to a+Δ, b sin θᵢ+a cos θᵢ=a+Δ. According to at least one embodiment, when it is assumed that

$$\frac{b}{\sqrt{{a}^{2} + {b}^{2}}} = cos α and \frac{a}{\sqrt{{a}^{2} + {b}^{2}}} = sin α , since$$

$$b sin {θ}_{i} + acos {θ}_{i} = \sqrt{{a}^{2} + {b}^{2}} ( sin {θ}_{i} cos α + cos {θ}_{i} sin α ) , \\ \sqrt{{a}^{2} + {b}^{2}} sin ( {θ}_{i} + {cos}^{- 1} \frac{b}{\sqrt{{a}^{2} + {b}^{2}}} ) = a + Δ and$$

$${θ}_{i} = {sin}^{- 1} \frac{a + Δ}{\sqrt{{a}^{2} + {b}^{2}}} - {cos}^{- 1} \frac{b}{\sqrt{{a}^{2} + {b}^{2}}} .$$

Therefore, in an exemplary embodiment of the present invention having the connecting space 11, the maximum rotatable angle θₘₐₓ of the electronic component 30 accommodated in the embedding space 10a satisfies the following Equation:

$${sin}^{- 1} \frac{a + Δ}{\sqrt{{a}^{2} + {b}^{2}}} - {cos}^{- 1} \frac{b}{\sqrt{{a}^{2} + {b}^{2}}} < {θ}_{max} .$$

According to at least one embodiment, a portion shown as a dotted line in FIG. 3D, which corresponds to the electronic component 30 having a short side a₂ and a long side b₂ and satisfying the following Equation: b₂>2a₂, shows the case in which the upper falling vertex Q″ of the electronic component 30 coincides with the point Pₕ or P″ₕ before the maximum rising vertex S″ of the electronic component 30 coincides with the point Pᵥ at the maximum connecting width w″ of the connecting space 11 depending on an increase in Δ₂. Referring to FIG. 3D, in the case in which the upper falling vertex Q″ of the electronic component 30 satisfying the following Equation: b₂>2a₂ coincides with the point Pₕ before the maximum rising vertex of the electronic component 30 coincides with the point P, at the maximum connecting width w″ of the connecting space 11 depending on the increase in Δ₂ or the upper falling vertex and the maximum rising vertex simultaneously coincide with the point Pₕ and the point Pᵥ, respectively,

$$sin {θ}_{max\_w max}^{″} = \frac{{a}_{2}}{{w}^{″}} = \frac{{a}_{2} + {Δ}_{2}}{{b}_{2}} and$$

$$tan {θ}_{max\_w max}^{″} \leq \frac{{a}_{2} + {Δ}_{2}}{{w}^{″}} Here , since$$

$$tan {θ}_{max\_w max}^{″} \leq \frac{{a}_{2} + {Δ}_{2}}{\sqrt{{b}_{2}^{2} - {( {a}_{2} + {Δ}_{2} )}^{2}}} and {w}^{″} = \frac{{a}_{2} {b}_{2}}{{a}_{2} + {Δ}_{2}} , \\ {a}_{2} {b}_{2} \leq ( {a}_{2} + {Δ}_{2} ) \sqrt{{b}_{2}^{2} - {( {a}_{2} + {Δ}_{2} )}^{2}} . \\ Thus , {( {a}_{2} {b}_{2} )}^{2} \leq {( {a}_{2} + {Δ}_{2} )}^{2} ( {b}_{2}^{2} - {( {a}_{2} + {Δ}_{2} )}^{2} ) .$$

According to at least one embodiment, when it is assumed that (a₂+Δ₂)²=t, since

$${t}^{2} - {b}_{2}^{2} t + {( {a}_{2} {b}_{2} )}^{2} < 0 and 0 < t , \\ 0 < t \leq \frac{{b}_{2}^{2} + {b}_{2} \sqrt{{b}_{2}^{2} - 4 {a}_{2}^{2}}}{2} .$$

In addition, since

$$0 < {Δ}_{2} , \\ 0 < {Δ}_{2} \leq \frac{\sqrt{{b}_{2}^{2} + {b}_{2} \sqrt{{b}_{2}^{2} - 4 {a}_{2}^{2}}}}{2} - {a}_{2} .$$

Thus, in the case in which b>2a, when the condition of Equation 1 is satisfied, the upper falling vertex Q″ of the electronic component 30 coincides with the point Pₕ (=P″ₕ) and the connecting space 11 has the maximum connecting width w″.

In the case in which b>2a and the condition of Equation 1 is satisfied, referring to FIG. 3D, a maximum rotatable angle θ″ₘₐₓ_{_{—}}_{wmax} of the electronic component 30 accommodated in the embedding space 10a having the connecting space 11 of the maximum connecting width w″ satisfies the following Equation:

$${θ}_{max\_wmax}^{″} = {sin}^{- 1} \frac{{a}_{2} + {Δ}_{2}}{{b}_{2}} .$$

Therefore, a maximum rotatable angle θₘₐₓ of the electronic component 30 accommodated in the embedding space 10a having an allowable connecting width for Δ satisfies the following Equation:

$${θ}_{max} \leq {sin}^{- 1} \frac{a + Δ}{b} .$$

Therefore, referring to FIGS. 1 and 3D, in the case in which b>2a and the condition of Equation 1 is satisfied, the maximum rotatable angle θₘₐₓ of the electronic component 30 accommodated in the embedding space 10a satisfies the following Equation:

$${sin}^{- 1} \frac{a + Δ}{\sqrt{{a}^{2} + {b}^{2}}} - {cos}^{- 1} \frac{b}{\sqrt{{a}^{2} + {b}^{2}}} < {θ}_{max} \leq {sin}^{- 1} \frac{a + Δ}{b} .$$

According to at least one embodiment,

$${sin}^{- 1} \frac{a + Δ}{b}$$

is a maximum rotatable angle θₘₐₓ_{_{—}}_{wmax} of the electronic component 30 in the case in which

$${w}_{max} = \frac{ab}{a + Δ} ,$$

and wₘₐₓ is a maximum connecting width of the connecting space 11 for any Δ.

Next, the case in which b>2a and the condition of Equation 1 is not satisfied will be described. According to at least one embodiment, in the case in which

$$Δ > \sqrt{\frac{{b}^{2} + b \sqrt{{b}^{2} - 4 {a}^{2}}}{2}} - a$$

or in the case in which

$$Δ \geq \sqrt{\frac{{b}^{2} + b \sqrt{{b}^{2} - 4 {a}^{2}}}{2}} - a ,$$

although not directly shown, the portion shown as the dotted line in FIG. 3D will have a structure similar to that of a dotted line showing the case of Δ in FIG. 3B. Thus, describing it using reference numerals of FIG. 3D, in the electronic component 30 satisfying the following Equation: b₂>2a₂, the maximum rising vertex S″ of the electronic component 30 coincides with the point Pᵥ before the upper falling vertex Q″ of the electronic component 30 coincides with the point Pₕ or P″ₕ at the maximum connecting width w″ of the connecting space 11 depending on an increase in Δ₂ or the maximum rising vertex and the upper falling vertex simultaneously coincide with the point Pᵥ and the point Pₕ or the point P″ₕ, respectively. Since this case has a structure similar to a condition of b␣2a as shown in FIGS. 3A to 3C, thus, the maximum rising vertex of the electronic component 30 coincides with the point Pᵥ before the upper falling vertex of the electronic component 30 coincides with the point Pₕ, a maximum rotatable angle θₘₐₓ of the electronic component 30 in the condition of b≦2a will be described.

Referring to FIGS. 3A to 3C, a maximum rotatable angle θ″ₘₐₓ_{_{—}}_{wmax} of the electronic component 30 accommodated in the embedding space 10a having the connecting space 11 of the maximum connecting width wₘₐₓ in the condition of b≦2a satisfies the following Equation:

$${θ}_{max\_wmax} = {cos}^{- 1} \frac{a}{a + Δ} .$$

Therefore, a maximum rotatable angle θₘₐₓ, of the electronic component 30 accommodated in the embedding space 10a having an allowable connecting width for Δ satisfies the following Equation:

$${θ}_{max} \leq {cos}^{- 1} \frac{a}{a + Δ} .$$

Therefore, referring to FIGS. 1 and 3A to 3C, in the case in which b>2a and the condition of Equation 1 is not satisfied, b>2a and

$$Δ \geq \sqrt{\frac{{b}^{2} + b \sqrt{{b}^{2} - 4 {a}^{2}}}{2}} - a ,$$

or the condition of b≦2a is satisfied, the maximum rotatable angle θₘₐₓ of the electronic component 30 accommodated in the embedding space 10a satisfies the following Equation:

$${sin}^{- 1} \frac{a + Δ}{\sqrt{{a}^{2} + {b}^{2}}} - {cos}^{- 1} \frac{b}{\sqrt{{a}^{2} + {b}^{2}}} < {θ}_{max} \leq {cos}^{- 1} \frac{a}{a + Δ} .$$

According to at least one embodiment,

$${cos}^{- 1} \frac{a}{a + Δ}$$

is a maximum rotatable angle θₘₐₓ_{_{—}}_{wmax} of the electronic component 30 in the case in which

$${w}_{max} = \frac{ab}{a + Δ} ,$$

wₘₐₓ is a maximum connecting width of the connecting space 11 for any Δ, and

$${sin}^{- 1} \frac{a + Δ}{\sqrt{{a}^{2} + {b}^{2}}} - {cos}^{- 1} \frac{b}{\sqrt{{a}^{2} + {b}^{2}}}$$

is a maximum rotatable angle in an independent cavity that does not have the connecting space 11 and has a length of a short side (when viewed on the plane) corresponding to a+Δ.

According to at least one embodiment, in a condition in which the maximum rotatable angle θₘₐₓ of the electronic component 30 accommodated in the embedding space 10a satisfies the following Equation:

$${θ}_{max} \leq \frac{π}{4} ,$$

the height h of the connecting space 11 (when viewed on the plane) satisfies the following Equation: w tan θₘₐₓ≦h≦a+Δ. According to at least one embodiment, referring to the dotted line rectangle of FIGS. 3A and 3C or 3B, the height h of the connecting space 11 (when viewed on the plane) at the time of maximum rotation of the electronic component 30 in a condition of

$${θ}_{max} \leq \frac{π}{4}$$

is larger than or equal to a height up to a point R or R′ at which an extension line of a lower long side of the electronic component 30 meets one side 11_{R} forming the connecting width of the connecting space 11, thus, one side 11_{R} coinciding with one short side 10as of the embedding space 10a and forming the connecting width of the connecting space 11. Here, w tan θₘₐₓ≦h.

According to at least one embodiment, in a condition in which the maximum rotatable angle θₘₐₓ of the electronic component 30 satisfies the following Equation:

$${θ}_{max} \geq \frac{π}{4} ,$$

the height h of the connecting space 11 (when viewed on the plane) satisfies the following Equation:

$$\frac{w}{tan {θ}_{max}} \leq h \leq a + Δ .$$

According to at least one embodiment, referring to a solid line rectangle of FIG. 3B and/or referring to FIG. 3D, the height h of the connecting space 11 (when viewed on the plane) at the time of maximum rotation of the electronic component 30 in a condition of

$${θ}_{max} \geq \frac{π}{4}$$

is larger than or equal to a height up to a point R_{Q} or R″_{Q} at which an extension line of one short side of the electronic component 30 meets the other side 11_{L} forming the connecting width of the connecting space 11, thus, other side 11_{L} coinciding with the lower long side 10al of the embedding space 10a and forming the connecting width of the connecting space 11. Here,

$$\frac{w}{tan {θ}_{max}} \leq h .$$

According to at least one embodiment, the height h of the connecting space 11 (when viewed on the plane) satisfies the following Equation: h≦2(b sin θₘₐₓ+a cos θₘₐₓ−(a+Δ)). Thus, the height h of the connecting space 11 (when viewed on the plane) is smaller than or equal to two times the height from the lower long side 10al of the embedding space 10a to the maximum falling vertex of the electronic component 30 at the time of maximum rotation of the electronic component 30 inserted into the embedding space 10a.

According to at least one embodiment,

$$\frac{b}{2} \leq w and Δ \leq ( \sqrt{2} - 1 ) a .$$

Next, referring to FIGS. 1 to 5, the two or more electronic components 30 of the electronic component-embedded substrate are separately accommodated in the embedding spaces 10a and 10b of the cavity 10, respectively. Here, the electronic components 30 separately accommodated in the embedding spaces 10a and 10b, respectively, are separately accommodated so as not to contact each other. According to at least one embodiment, the electronic component 30 is a chip element, a passive element, or an active element. According to at least one embodiment, the electronic component 30 is a passive element having an electrode. Here, the passive element is a capacitor or an inductor. According to at least one embodiment, the passive element is a multilayer capacitor.

According to at least one embodiment, referring to FIGS. 1 and 3A to 3C, the cavity 10 includes the first and second embedding spaces 10a and 10b connected to each other by the connecting space 11, and the electronic components 30 is separately accommodated in the embedding spaces 10a and 10b, respectively. In addition, referring to FIGS. 2A and 2B, the cavity 10 includes first to third embedding spaces 10a to 10c, a first connecting space 11 connecting the first and second embedding spaces 10a and 10b to each other, and a second connecting space 11 connecting the second and third embedding spaces 10b and 10c to each other. Here, referring to FIG. 2A, one side 11_{R} of a connecting width of the first connecting space 11 coincides with one short side 10as of the first embedding space 10a and meet an upper long side of the second embedding space 10b, and the other side 11L of the first connecting space 11 meets a lower long side 10al of the first embedding space 10a and coincide with the other short side of the second embedding space 10b. In addition, one side of a connecting width of the second connecting space 11 coincides with one short side of the third embedding space 10c and meet a lower long side of the second embedding space 10b, and the other side the second connecting space 11 meets an upper long side of the third embedding space 10c and coincide with the other short side of the second embedding space 10b. Thus, the other side 11L forming the connecting width of the first and second connecting spaces 11 and the other short side of the second embedding space 10b coincides with each other as one line and form the same surface. According to at least one embodiment, referring to FIG. 2A, the cavity 10 is formed in a zigzag structure. In addition, referring to FIG. 2B, the cavity 10 is formed in a step structure. Further, referring to FIG. 2C, the cavity 10 includes four embedding spaces 10a to 10d and three connecting spaces 11 connecting between the embedding spaces. Here, the cavity 10 is formed in a zigzag structure. Alternatively, although not shown, the cavity 10 is formed in a step structure. Generally referring to FIGS. 1 to 3C, in the case in which n is a natural number of 2 or more, the cavity 10 includes n embedding spaces and n−1 connecting spaces 11 connecting between two embedding spaces.

Another embodiment of the electronic component-embedded substrate will be described with reference to FIG. 4. Referring to FIG. 4, one end portion of at least one side 11R forming a connecting width of a connecting space 11 is connected to a short side of any one 10a of first and second embedding spaces 10a and 10b so as to coincide therewith. In addition, the other end portion of the at least one side 11_{R} is bent and meet a long side of the other embedding space 10b. According to at least one embodiment, referring to FIG. 4, one side 11_{R} of the connecting width of the connecting space 11 coincides with one short side 10as of the first embedding space 10a and meet an upper long side of the second embedding space 10b, and one side of the other side 11_{L} is bent at a portion at which it meets a lower long side 10al of the first embedding space 10a and then meet the lower long side 10al of the first embedding space 10a and the other side thereof coincides with the other short side of the second embedding space 10b. Here, the connecting width w of the connecting space 11 is a long width of the connecting space 11 formed by a distal end of the other end portion, and the long width of the connecting space 11 is larger than a short width w_{L} of the connecting space 11 formed by a bent point of the other end portion. In addition, here, a maximum rotation angle is formed at a distal end of the other end portion at the time of maximum rotation of the electronic component 30 accommodated in the embedding space 10a or 10b. Thus, when the electronic component 30 is maximally rotated, a lower long side of the electronic component 30 coincides with an inclined side between a distal end point P of the other end portion meeting the lower long side 10al of the first embedding space 10a and the bent point P_{L} of the other end portion or the distal end point P of the other end portion becomes a rotation origin point of the maximum rotation angle of the electronic component 30.

According to at least one embodiment, referring to FIG. 5, the electronic component-embedded substrate according to at least one embodiment further includes an insulating layer 110 stacked so as to cover the cavity 10 into which the electronic components 30 are inserted and having a plurality of vias 120a formed therein so as to be electrically connected to the electronic components 30.

Next, in order to solve the above-mentioned problem, an electronic component-embedded substrate according to a second aspect of the present invention will be described in detail with reference to the accompanying drawings. Here, a description will be provided with reference to exemplary embodiments of the electronic component-embedded substrate according to a first aspect of the present invention described above and FIGS. 1 to 4.

FIG. 5 is a cross-sectional view schematically showing an electronic component-embedded substrate according to another embodiment of the invention.

Referring to FIG. 5, the electronic component-embedded substrate according to at least one embodiment is configured to include the core substrate 100, the cavity 10, two or more electronic components 30, and the insulating layer 110. According to at least one embodiment, the cavity 10 and the two or more electronic components 30 will be described with reference to FIGS. 1 to 4.

First, referring to FIGS. 1 to 5, the cavity 10 is formed in the core substrate 100. According to at least one embodiment, referring to FIG. 5, internal circuit patterns is formed on the core substrate 100. According to at least one embodiment, the cavity 10 is formed so as to penetrate through a region in which the internal circuit patterns are not formed on the core substrate 100. The cavity 10 includes two or more embedding spaces 10a and 10b. According to at least one embodiment, the cavity 10 includes the first embedding space 10a, which is one of the two or more embedding spaces 10a and 10b, the second embedding space 10b, which is the other of the two or more embedding spaces 10a and 10b, and the connecting space 11 connecting the first and second embedding spaces 10a and 10b to each other. The first embedding space 10a is formed in a horizontal rectangular shape when viewed on the plane. The connecting space 11 is connected to a portion of the lower long side 10al of the first embedding space 10a and a portion of the upper long side of the second embedding space 10b. According to at least one embodiment, the connecting width of the connecting space 11 means a section length at which the first embedding space 10a and the connecting space 11 are connected to each other or a section length at which the second embedding space 10b and the connecting space 11 are connected to each other. One side 11_{R} (when viewed on the plane) forming the connecting width of the connecting space 11 coincides with one short side 10as of the first embedding space 10a, and the other side 11_{L} (when viewed on the plane) meets the lower long side 10al of the first embedding space 10a. Here, one side 11_{R} (when viewed on the plane) of the connecting width of the connecting space 11 meets the upper long side of the second embedding space 10b, and the other side 11_{L} (when viewed on the plane) coincides with the other short side of the second embedding space 10b. The second embedding space 10b is formed in a horizontal rectangular shape when viewed on the plane. According to at least one embodiment, the second embedding space 10b has the other short side coinciding with the other side (when viewed on the plane) of the connecting width of the connecting space 11 and the upper long side meeting one side 11_{R} (when viewed on the plane) of the connecting width.

Next, the two or more electrode components 30 are separately accommodated in the embedding spaces 10a and 10b of the cavity 10, respectively. According to at least one embodiment, the electronic components 30 is maximally rotated at a point at which a side of the connecting space 11 and long sides of the embedding spaces 10a and 10b meet each other. In addition, the electronic components 30 accommodated in the cavity 10 are separately accommodated in the embedding spaces 10a and 10b of the cavity 10, respectively, so as not to contact each other when they are maximally rotated. According to at least one embodiment, the electronic component 30 is a chip element, a passive element, or an active element. According to at least one embodiment, the electronic component 30 is a passive element having an electrode. According to at least one embodiment, the electronic component 30 is a multilayer capacitor.

According to at least one embodiment, a structure of the cavity 10 will be described in more detail with reference to FIGS. 1 to 4. According to at least one embodiment, the connecting width w of the connecting space 11 satisfies the following Equation:

$$a sin {θ}_{i} < w \leq \frac{ab}{a + Δ} .$$

According to at least one embodiment, a is a length of a short side (when viewed on the plane) of the electronic component 30, b is a length of a long side (when viewed on the plane) of the electronic component 30, and Δ is a difference between a length of a short side of the embedding space 10a or 10b and a length of the short side of the electronic component 30. In addition, 8i is a maximum rotatable angle in an independent cavity that does not have the connecting space 11 and has a length of a short side (when viewed on the plane) corresponding to a+Δ.

According to at least one embodiment, the larger the difference Δ between the length a+Δ of the short side of the embedding space 10a or 10b and the length a of the short side of the electronic component 30, the larger the maximum rotatable angle of the electronic component 30 at the point P at which the other side 11_{L} (when viewed on the plane) forming the connecting width of the connecting space 11 and the lower long side of the first embedding space meet each other and the larger the maximum value of the connecting width w of the connecting space 11. According to at least one embodiment, the maximum value of the connecting width or the maximum connecting width of the connecting space 11 means a connecting width at which the electronic component 30 inserted into the embedding space 10a or 10b is rotated at a maximum rotation angle at the point P without getting out to the connecting space 11. Thus, referring to FIGS. 1 and 3A to 3D, in the maximum value of the connecting width w of the connecting space 11, a maximum rising vertex S of two upper vertexes of the electronic component 30 coincides with a point Pᵥ at which the extension line passing through the point P, which is the rotation origin point, and an upper long side of the embedding space 10a or 10b meet each other or an upper falling vertex Q or Q″ (See FIG. 3C or 3D), which is the other of the two upper vertexes of the electronic component 30 coincides with a point Pₕ.

According to at least one embodiment, in the case in which the maximum rising vertex S of the electronic component 30 coincides with the point Pᵥ in FIGS. 3A to 3D and in the case in which the upper falling vertex Q or Q″ of the electronic component 30 coincides with the point Pₕ in FIGS. 3C and/or 3D, the maximum connecting width wₘₐₓ of the connecting space 11 for any Δ satisfies the following Equation:

$${w}_{max} = \frac{ab}{a + Δ} .$$

Since the maximum connecting width of the connecting space 11 for any Δ is

$$\frac{ab}{a + Δ} ,$$

an allowable connecting width w of the connecting space 11 for any Δ is

$$w \leq \frac{ab}{a + Δ} .$$

According to at least one embodiment, according to one embodiment of the invention including the cavity 10 having the connecting space 11, the maximum rotatable angle is larger than a maximum rotatable angle in an independent cavity that does not have the connecting space 11 and have a length of the short side (when viewed on the plane) corresponding to a+Δ. Here, referring to the electronic component 30 shown as the dotted line rectangle including vertexes Sᵢ, Qᵢ, and Tᵢ of FIG. 1, the connecting width w of the connecting space 11 satisfies the following Equation: a sin θᵢ<w.

According to at least one embodiment, Δ satisfies the following Equation: 0<Δ<b−a. Here, a height h of the connecting space 11 (when viewed on the plane), which is a distance between a long side 10al of the first embedding space 10a and a long side of the second embedding space 10b neighboring to the first embedding space 10a, satisfies the following Equation: h≦a+Δ.

According to at least one embodiment, referring to FIGS. 3A to 3D, the height h of the connecting space 11 (when viewed on the plane) satisfies the following Equation: b sin θₘₐₓ+a cos θₘₐₓ−(a+Δ)<h. θₘₐₓ is a maximum rotatable angle of the electronic component 30 accommodated in the embedding space 10a or 10b. Here, b sin θₘₐₓ+a cos θₘₐₓ−(a+Δ) is a height from the lower long side 10al of the embedding space 10a to the maximum falling vertex of the electronic component 30 when the electronic component 30 inserted into the embedding space 10a or 10b is maximally rotated.

According to at least one embodiment, the maximum rotatable angle θₘₐₓ of the electronic component 30 accommodated in the embedding space 10a or 10b in a condition of the following Equation 1:

$$0 < Δ < \sqrt{\frac{{b}^{2} + b \sqrt{{b}^{2} - 4 {a}^{2}}}{2}} - a$$

and b>2a satisfies the following Equation:

$${sin}^{- 1} \frac{a + Δ}{\sqrt{{a}^{2} + {b}^{2}}} - {cos}^{- 1} \frac{b}{\sqrt{{a}^{2} + {b}^{2}}} < {θ}_{max} \leq {sin}^{- 1} \frac{a + Δ}{b} .$$

According to at least one embodiment, referring to FIG. 1, the maximum rotation angle θᵢ in the independent cavity that does not have the connecting space 11 and has the length of the short side corresponding to a+Δ satisfies the following Equation:

$${θ}_{i} = {sin}^{- 1} \frac{a + Δ}{\sqrt{{a}^{2} + {b}^{2}}} - {cos}^{- 1} \frac{b}{\sqrt{{a}^{2} + {b}^{2}}} .$$

Therefore, in an exemplary embodiment of the present invention including the connecting space 11, the maximum rotatable angle θₘₐₓ of the electronic component 30 accommodated in the embedding space 10a or 10b satisfies the following Equation:

$${sin}^{- 1} \frac{a + Δ}{\sqrt{{a}^{2} + {b}^{2}}} - {cos}^{- 1} \frac{b}{\sqrt{{a}^{2} + {b}^{2}}} < {θ}_{max} .$$

According to at least one embodiment, referring to FIG. 3D, in the case in which the upper falling vertex Q″ of the electronic component 30 coincides with the point Pₕ before the maximum rising vertex of the electronic component 30 coincides with the point Pᵥ depending on the maximum rotation of electronic component 30 satisfying the following Equation: b₂>2a₂ at the maximum connecting width w″ of the connecting space 11 depending on the increase in Δ₂ or the upper falling vertex and the maximum rising vertex simultaneously coincide with the point Pₕ and the point Pᵥ, respectively,

$$0 < {Δ}_{2} \leq \sqrt{\frac{{b}_{2}^{2} + {b}_{2} \sqrt{{b}_{2}^{2} - 4 {a}_{2}^{2}}}{2}} - {a}_{2} .$$

Thus, in the case in which b>2a, when the condition of Equation 1 is satisfied, the upper falling vertex Q″ of the electronic component 30 coincides with the point Pₕ (=P″ₕ) and the connecting space 11 has the maximum connecting width w″. According to at least one embodiment, the maximum rotatable angle θ″ₘₐₓ_{_{—}}_{wmax} of the electronic component 30 accommodated in the embedding space 10a or 10b having the connecting space 11 of the maximum connecting width w″ satisfies the following Equation:

$${θ}_{max \_ wmax}^{″} = {sin}^{- 1} \frac{{a}_{2} + {Δ}_{2}}{{b}_{2}} .$$

Therefore, according to the present exemplary embodiment, the maximum rotatable angle θₘₐₓ of the electronic component 30 accommodated in the embedding space 10a or 10b having an allowable connecting width for Δ satisfies the following Equation:

$${θ}_{max} \leq {sin}^{- 1} \frac{a + Δ}{b} .$$

According to at least one embodiment, the maximum rotatable angle θₘₐₓ of the electronic component 30 in a condition in which Equation 1 is not satisfied or b≦2a will be described. First, in the case in which b>2a and a condition of Equation 1 is not satisfied, although not directly shown, the portion shown as the dotted line in FIG. 3D will have a structure similar to that of a dotted line showing the case of Δ in FIG. 3B. Since this case has a structure similar to a condition of b≦2a as shown in FIGS. 3A to 3C, thus, the maximum rising vertex of the electronic component 30 coincides with the point Pᵥ before the upper falling vertex of the electronic component 30 coincides with the point Pₕ, the maximum rotatable angle θₘₐₓ of the electronic component 30 is similarly represented in the case in which b>2a and the condition of Equation 1 is not satisfied and in the condition of b≦2a. Referring to FIGS. 3A to 3C, the maximum rotatable angle θₘₐₓ_{_{—}}_{wmax} of the electronic component 30 accommodated in the embedding space 10a or 10b having the connecting space 11 of the maximum connecting width wₘₐₓ in the condition of b≦2a satisfies the following Equation:

$${θ}_{max \_ wmax} = {cos}^{- 1} \frac{a}{a + Δ} .$$

Therefore, the maximum rotatable angle θₘₐₓ of the electronic component 30 accommodated in the embedding space 10a or 10b having an allowable connecting width for Δ satisfies the following Equation:

$${θ}_{max} \leq {cos}^{- 1} \frac{a}{a + Δ} .$$

Therefore, in the case in which b>2a and the condition of Equation 1 is not satisfied, b>2a and

$$Δ \geq \sqrt{\frac{{b}^{2} + b \sqrt{{b}^{2} - 4 {a}^{2}}}{2}} - a ,$$

or the condition of b≦2a is satisfied, the maximum rotatable angle θₘₐₓ of the electronic component 30 accommodated in the embedding space 10a or 10b satisfies the following Equation:

$${sin}^{- 1} \frac{a + Δ}{\sqrt{{a}^{2} + {b}^{2}}} - {cos}^{- 1} \frac{b}{\sqrt{{a}^{2} + {b}^{2}}} < {θ}_{max} \leq {cos}^{- 1} \frac{a}{a + Δ} .$$

Further, according to at least one embodiment, referring to a rectangle shown as a dotted line in FIGS. 3A and 3C or 3B, in a condition in which the maximum rotatable angle θₘₐₓ of the electronic component 30 accommodated in the embedding space 10a or 10b satisfies the following Equation:

$${θ}_{max} \leq \frac{π}{4} ,$$

the height h of the connecting space 11 (when viewed on the plane) satisfies the following Equation: w tan θₘₐₓ≦h≦a+Δ. Further, referring to a rectangle shown as a solid line of FIG. 3B and/or FIG. 3D, in a condition in which the maximum rotatable angle θₘₐₓ of the electronic component 30 satisfies the following Equation:

$${θ}_{max} \geq \frac{π}{4} ,$$

the height h of the connecting space 11 (when viewed on the plane) satisfies the following Equation:

$$\frac{w}{tan {θ}_{max}} \leq h \leq a + Δ .$$

According to at least one embodiment, the height h of the connecting space 11 (when viewed on the plane) satisfies the following Equation: h≦2(b sin θₘₐₓ+a cos θₘₐₓ−(a+Δ)).

According to at least one embodiment,

$$\frac{b}{2} \leq w$$

$$and$$

$$Δ \leq ( \sqrt{2} - 1 ) a .$$

According to at least one embodiment, generally referring to FIGS. 1 to 3C, in the case in which n is a natural number of 2 or more, the cavity 10 includes n embedding spaces 10a and 10b and n−1 connecting spaces 11 connecting between two embedding spaces 10a and 10b.

According to at least one embodiment, referring to FIG. 4, one end portion of at least one side forming the connecting width of the connecting space 11 is connected to the short side of any one 10a or 10b of the first and second embedding spaces 10a and 10b so as to coincide therewith. In addition, the other end portion of the at least one side is bent and meet the long side of the other embedding space 10a or 10b. According to at least one embodiment, the connecting width w of the connecting space 11 is a long width of the connecting space 11 formed by a distal end of the other end portion, and the long width of the connecting space 11 is larger than a short width W_{L} of the connecting space 11 formed by a bent point of the other end portion. According to at least one embodiment, a maximum rotation angle is formed at a distal end of the other end portion at the time of maximum rotation of the electronic component 30 accommodated in the embedding space 10a or 10b.

Next, referring to FIG. 5, upper and lower insulating layers 110 of the electronic component-embedded substrate covers the electronic components 30 embedded in the cavity 10. Here, a plurality of vias 120a are formed in at least one of the upper and lower insulating layers 111 and 113. The vias 120a are electrically connected to electrodes 31 (See FIGS. 2A to 2C) of the electronic components 30 while penetrating through at least one of the upper and lower insulating layers 111 and 113. FIG. 5 shows that the vias 120a are formed in the upper insulating layer 111. According to at least one embodiment, referring to FIG. 5, outer circuit patterns electrically connected to the vias 120a is formed on the insulating layer 110.

Manufacturing Method of Electronic Component-Embedded Substrate

Next, a manufacturing method of an electronic component-embedded substrate according to a third aspect of the present invention will be described in detail with reference to the accompanying drawings. According to at least one embodiment, a description will be provided with reference to the electronic component-embedded substrates according to first and second aspects of the present invention described above and FIGS. 1 to 5. Therefore, overlapped descriptions will be omitted.

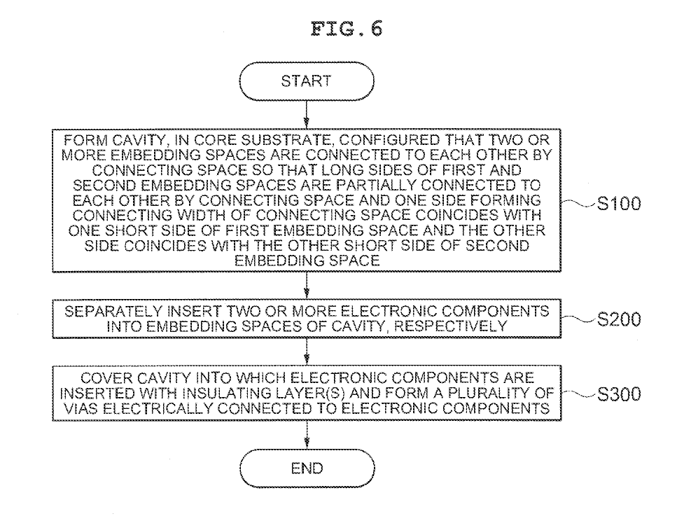

FIG. 6 is a flow chart schematically showing a manufacturing method of an electronic component-embedded substrate according to another embodiment of the invention.

Referring to FIG. 6, a manufacturing method of an electronic component-embedded substrate according to at least one embodiment includes a cavity forming step S100, an electronic component embedding step S200, and an insulating layer and via forming step S300. The respective steps will be described in detail with reference to the accompanying drawings. A structure of the cavity 100 in the cavity forming step S100 will be described with reference to FIGS. 1 and 3A to 3D.

According to at least one embodiment, referring to FIG. 6, in the cavity forming step S100, the cavity 10 configured that the two or more embedding spaces 10a and 10b having a rectangular shape when viewed on the plane are connected to each other by the connecting space 11 is formed in the core substrate 100. According to at least one embodiment, neighboring long sides of the first and second embedding spaces 10a and 10b are partially connected to each other by the connecting space 11. In addition, one side 11_{R} (when viewed on the plane) of the connecting space 11 forming the connecting width of the connecting space 11 connecting the first and second embedding spaces 10a and 10b coincides with one short side 10as of the first embedding space 10a, and the other side 11_{L} (when viewed on the plane) thereof coincides with the other short side of the second embedding space 10b. According to at least one embodiment, the two or more embedding spaces 10a and 10b of the cavity 10 are spaces into which two or more electronic components 30 are separately inserted without contacting each other.

According to at least one embodiment, in the cavity forming step S100, referring to FIGS. 1 and 3A to 3D, the connecting width w of the connecting space 11 satisfies the following Equation:

$$a sin {θ}_{i} < w \leq \frac{ab}{a + Δ} .$$

According to at least one embodiment, a is a length of a short side (when viewed on the plane) of the electronic component 30, b is a length of a long side (when viewed on the plane) of the electronic component 30, and Δ is a difference between a length a+Δ of a short side of the embedding space 10a or 10b and a length a of the short side of the electronic component 30. θᵢ is a maximum rotatable angle in an independent cavity that does not have the connecting space 11 and has a length of a short side (when viewed on the plane) corresponding to a+Δ. In an exemplary embodiment of the present invention, since the connecting space 11 is provided in the cavity 10, a sin θᵢ<w so that the maximum rotation angle of the electronic component 30 is larger than that of the electronic component 30 in the case in which the connecting space 11 is not provided. In addition, referring to FIGS. 3A to 3D, the maximum connecting width wₘₐₓ of the connecting space 11 for any Δ satisfies the following Equation:

$${w}_{max} = \frac{ab}{a + Δ} .$$

Therefore, the allowable connecting width w of the connecting space 11 for any Δ satisfies the following Equation:

$$w \leq \frac{ab}{a + Δ} .$$

According to at least one embodiment, in the cavity forming step S100, Δ satisfies the following Equation: 0<Δ<b−a. Further, in the cavity forming step S100, the cavity 10 is formed so that a height h of the connecting space 11 (when viewed on the plane), which is a distance between a long side 10al of the first embedding space 10a and a long side of the second embedding space 10b, satisfies the following Equation: h≦a+Δ.

Further, according to at least one embodiment, in the cavity forming step S100, the cavity 10 is formed so that the maximum rotatable angle θₘₐₓ of the electronic component 30 accommodated in the embedding space 10a or 10b is implemented. According to at least one embodiment, generally referring to FIGS. 1 and 3D, the cavity 10 is formed so that the upper falling vertex Q″ of the electronic component 30 coincides with the point Pₕ before the maximum rising vertex of the electronic component 30 coincides with the point Pᵥ at the time of maximum rotation of electronic component 30 satisfying the following Equation: b>2a at the maximum connecting width wₘₐₓ of the connecting space 11 depending on the increase in Δ or the upper falling vertex and the maximum rising vertex simultaneously coincide with the point Pₕ and the point Pᵥ, respectively. According to at least one embodiment, the maximum rotatable angle θₘₐₓ of the electronic component 30 accommodated in the embedding space 10a or 10b is larger than a maximum rotatable angle in an independent cavity that does not have the connecting space 11 and has a length of the short side corresponding to a+Δ. Thus, the following Equation:

$${sin}^{- 1} \frac{a + Δ}{\sqrt{{a}^{2} + {b}^{2}}} - {cos}^{- 1} \frac{b}{\sqrt{{a}^{2} + {b}^{2}}} < {θ}_{max}$$

is satisfied. In addition, referring to FIG. 3D, in the case in which the upper falling vertex Q″ of the electronic component 30 coincides with the point Pₕ before the maximum rising vertex of the electronic component 30 coincides with the point Pᵥ depending on the maximum rotation of electronic component 30 satisfying the following Equation: b₂>2a₂ at the maximum connecting width w″ of the connecting space 11 depending on the increase in Δ₂ or the upper falling vertex and the maximum rising vertex simultaneously coincide with the point Pₕ and the point Pᵥ, respectively,

$$0 < {Δ}_{2} \leq \sqrt{\frac{{b}_{2}^{2} + {b}_{2} \sqrt{{b}_{2}^{2} - 4 {a}_{2}^{2}}}{2}} - {a}_{2} .$$

In this case, the maximum rotatable angle θ″ₘₐₓ_{_{—}}_{wmax} of the electronic component 30 accommodated in the embedding space 10a or 10b having the connecting space 11 of the maximum connecting width w″ satisfies the following Equation:

$${θ}_{m a x\_w max}^{″} = {sin}^{- 1} \frac{{a}_{2} + {Δ}_{2}}{{b}_{2}} .$$

Therefore, the maximum rotatable angle θₘₐₓ of the electronic component 30 accommodated in the embedding space 10a or 10b having the allowable connecting width for a in a condition of the following Equation 1:

$$0 < Δ < \sqrt{\frac{{b}^{2} + b \sqrt{{b}^{2} - 4 {a}^{2}}}{2}} - a$$

and b>2a satisfies the following Equation:

$${sin}^{- 1} \frac{a + Δ}{\sqrt{{a}^{2} + {b}^{2}}} - {cos}^{- 1} \frac{b}{\sqrt{{a}^{2} + {b}^{2}}} < {θ}_{m ax} \leq {sin}^{- 1} \frac{a + Δ}{b} .$$

According to at least one embodiment, the maximum rotatable angle θₘₐₓ of the electronic component 30 in a condition in which b>2a and Equation 1 is not satisfied or b≦2a will be described. First, the case in which b>2a and the condition of Equation 1 is not satisfied has a structure similar to a condition of b≦2a as shown in FIGS. 3A to 3C since the maximum rising vertex of the electronic component 30 coincides with the point Pᵥ before the upper falling vertex of the electronic component 30 coincides with the point Pₕ, although not directly shown. According to at least one embodiment, the maximum rotatable angle θₘₐₓ of the electronic component 30 is similarly represented. Referring to FIGS. 3A to 3C, the maximum rotatable angle θ″ₘₐₓ_{_{—}}_{wmax} of the electronic component 30 accommodated in the embedding space 10a or 10b having the connecting space 11 of the maximum connecting width wₘₐₓ in the condition of b≦2a satisfies the following Equation:

$${θ}_{max\_wmax} = {cos}^{- 1} \frac{a}{a + Δ} .$$

Therefore, the maximum rotatable angle θₘₐₓ of the electronic component 30 accommodated in the embedding space 10a or 10b having an allowable connecting width for Δ satisfies the following Equation:

$${θ}_{m ax} \leq {cos}^{- 1} \frac{a}{a + Δ} .$$

Therefore, in the cavity forming step S100, the cavity 10 is formed so that the maximum rotatable angle θₘₐₓ of the electronic component 30 accommodated in the embedding space 10a or 10b satisfies the following Equation:

$${sin}^{- 1} \frac{a + Δ}{\sqrt{{a}^{2} + {b}^{2}}} - {cos}^{- 1} \frac{b}{\sqrt{{a}^{2} + {b}^{2}}} < {θ}_{m ax} \leq {cos}^{- 1} \frac{a}{a + Δ}$$

in the case in which b>2a and the condition of Equation 1 is not satisfied or the condition of b≦2a is satisfied.

According to at least one embodiment, describing the cavity forming step S100 of FIG. 6 with reference to FIGS. 3A to 3D, in the cavity forming step S100, the cavity 10 is formed so that the height h of the connecting space 11 (when viewed on the plane) satisfies the following Equation: b sin θₘₐₓ+a cos θₘₐₓ−(a+Δ)<h. Here, b sin θₘₐₓ+a cos θₘₐₓ−(a+Δ) is a height from the lower long side 10al of the embedding space 10a to the maximum falling vertex of the electronic component 30 when the electronic component 30 inserted into the embedding space 10a or 10b is maximally rotated.

According to at least one embodiment, in the cavity forming step S100, the cavity 10 is formed so that the height h of the connecting space 11 (when viewed on the plane) satisfies the following Equation: h≦2(b sin θₘₐₓ+a cos θₘₐₓ−(a+Δ)). Thus, the height h of the connecting space 11 (when viewed on the plane) is smaller than or equal to two times the height from the lower long side 10al of the embedding space 10a to the maximum falling vertex of the electronic component 30 at the time of maximum rotation of the electronic component 30 inserted into the embedding space 10a or 10b.

According to at least one embodiment, referring to a rectangle shown as a dotted line in FIGS. 3A and 3C or 3B, in the cavity forming step S100 of FIG. 6, the cavity 10 is formed so that the height h of the connecting space 11 (when viewed on the plane) satisfies the following Equation: w tan θₘₐₓ≦h≦a+Δ in a condition in which the maximum rotatable angle θₘₐₓ of the electronic component 30 accommodated in the embedding space 10a or 10b satisfies the following Equation:

$${θ}_{m ax} \leq \frac{π}{4} .$$

Further, referring to a rectangle shown as a solid line of FIG. 3B and/or FIG. 3D, the cavity 10 is formed so that the height h of the connecting space 11 (when viewed on the plane) satisfies the following Equation:

$$\frac{w}{tan {θ}_{m ax}} \leq h \leq a + Δ ,$$

in a condition in which the maximum rotatable angle θₘₐₓ of the electronic component 30 satisfies the following Equation:

$${θ}_{m ax} \geq \frac{π}{4} .$$

In another embodiment, in the cavity forming step S100, the cavity 10 is formed so that

$$\frac{b}{2} \leq w and Δ \leq ( \sqrt{2} - 1 ) a .$$

Next, referring to FIG. 6, in the electronic component embedding step S200, the two or more electronic components 30 are separately inserted in the embedding spaces 10a and 10b of the cavity 10, respectively.

Continuously referring to FIG. 6, in the insulating and via forming step S300, the cavity 10 into which the electronic components 30 are inserted is covered with the insulating layer(s) 110. In addition, the plurality of vias 120a electrically connected to the electronic components 30 while penetrating through the insulating layer(s) 110 are formed.

According to various embodiments of the invention, the cavity structure is improved so that one cavity includes the two or more embedding spaces into which the electronic components are to be inserted, respectively, and the connecting space connecting the embedding spaces to each other, thereby making it possible to prevent a short-circuit between the electronic components inserted into the cavity.

According to at least one embodiment, a shift range of the electronic component is limited to a range within an allowable rotation radius so that the electronic component inserted into the embedding space of the cavity does not get out to the connecting space, thereby making it possible to improve an eccentricity defect of the via.

Further, according to at least one embodiment, only portions of long sides of the embedding spaces are connected to each other by the connecting space to generally decrease a margin space except for the electronic components in the cavity, thereby making it possible to improve a void problem, or the like, on the insulating layer stacked on the cavity.

Terms used herein are provided to explain embodiments, not limiting the invention. Throughout this specification, the singular form includes the plural form unless the context clearly indicates otherwise. When terms “comprises” and/or “comprising” used herein do not preclude existence and addition of another component, step, operation and/or device, in addition to the above-mentioned component, step, operation and/or device.

Embodiments of the invention may suitably comprise, consist or consist essentially of the elements disclosed and may be practiced in the absence of an element not disclosed. According to at least one embodiment, it can be recognized by those skilled in the art that certain steps can be combined into a single step.

The terms and words used in the specification and claims should not be interpreted as being limited to typical meanings or dictionary definitions, but should be interpreted as having meanings and concepts relevant to the technical scope of the invention based on the rule according to which an inventor can appropriately define the concept of the term to describe the best method he or she knows for carrying out the invention.

The terms “first,” “second,” “third,” “fourth,” and the like in the description and in the claims, if any, are used for distinguishing between similar elements and not necessarily for describing a particular sequential or chronological order. It is to be understood that the terms so used are interchangeable under appropriate circumstances such that the embodiments of the invention described herein are, for example, capable of operation in sequences other than those illustrated or otherwise described herein. Similarly, if a method is described herein as comprising a series of steps, the order of such steps as presented herein is not necessarily the only order in which such steps may be performed, and certain of the stated steps may possibly be omitted and/or certain other steps not described herein may possibly be added to the method.

The singular forms “a,” “an,” and “the” include plural referents, unless the context clearly dictates otherwise.

As used herein and in the appended claims, the words “comprise,” “has,” and “include” and all grammatical variations thereof are each intended to have an open, non-limiting meaning that does not exclude additional elements or steps.

As used herein, it will be understood that unless a term such as ‘directly’ is not used in a connection, coupling, or disposition relationship between one component and another component, one component may be ‘directly connected to’, ‘directly coupled to’ or ‘directly disposed to’ another element or be connected to, coupled to, or disposed to another element, having the other element intervening therebetween.

As used herein, the terms “left,” “right,” “front,” “back,” “top,” “bottom,” “over,” “under,” and the like in the description and in the claims, if any, are used for descriptive purposes and not necessarily for describing permanent relative positions. It is to be understood that the terms so used are interchangeable under appropriate circumstances such that the embodiments of the invention described herein are, for example, capable of operation in other orientations than those illustrated or otherwise described herein. The term “coupled,” as used herein, is defined as directly or indirectly connected in an electrical or non-electrical manner. Objects described herein as being “adjacent to” each other may be in physical contact with each other, in close proximity to each other, or in the same general region or area as each other, as appropriate for the context in which the phrase is used. Occurrences of the phrase “according to an embodiment” herein do not necessarily all refer to the same embodiment.

Ranges may be expressed herein as from about one particular value, and/or to about another particular value. When such a range is expressed, it is to be understood that another embodiment is from the one particular value and/or to the other particular value, along with all combinations within said range.

Although the invention has been described in detail, it should be understood that various changes, substitutions, and alterations can be made hereupon without departing from the principle and scope of the invention. Accordingly, the scope of the invention should be determined by the following claims and their appropriate legal equivalents.

What is claimed is:

1. An electronic component-embedded substrate, comprising:
a cavity formed in a core substrate and comprising two or more embedding spaces, which have a rectangular shape, when viewed on a plane, and are connected to each other by a connecting space; and
two or more electronic components separately accommodated in the embedding spaces of the cavity, respectively,
wherein neighboring long sides of first and second embedding spaces connected to each other by the connecting space are partially connected to each other by the connecting space, and
one side, when viewed on the plane, forming a connecting width of the connecting space connecting the first and second embedding spaces to each other coincides with one short side of the first embedding space, and the other side, when viewed on the plane, coincides with the other short side of the second embedding space.

2. The electronic component-embedded substrate according to claim 1, wherein the connecting width w of the connecting space satisfies the following Equation:
$$a sin {θ}_{i} < w \leq \frac{ab}{a + Δ} ,$$
wherein a is a length of a short side, when viewed on the plane, of the electronic component, b is a length of a long side, when viewed on the plane, of the electronic component, Δ is a difference between a length of a short side of the embedding space and a length of the short side of the electronic component, and θᵢ is a maximum rotatable angle in an independent cavity that does not have the connecting space and has a length of a short side, when viewed on the plane, corresponding to a+Δ.

3. The electronic component-embedded substrate according to claim 2, wherein Δ satisfies the following Equation: 0<Δ<b−a, and
wherein a height h of the connecting space, when viewed on the plane, which is a distance between the long side of the first embedding space and the long side of the second embedding space neighboring to the first embedding space, satisfies the following Equation: h≦a+Δ.

4. The electronic component-embedded substrate according to claim 3, wherein the height h of the connecting space, when viewed on the plane, satisfies the following Equation: b sin θₘₐₓ+a cos θₘₐₓ−(a+Δ)<h,
wherein θₘₐₓ is a maximum rotatable angle of the electronic component accommodated in the embedding space.

5. The electronic component-embedded substrate according to claim 3, wherein a maximum rotatable angle θₘₐₓ of the electronic component accommodated in the embedding space in a condition of the following Equation 1:
$$0 < Δ \leq \sqrt{\frac{{b}^{2} + b \sqrt{{b}^{2} - 4 {a}^{2}}}{2}} - a$$
and b>2a satisfies the following Equation:
$${sin}^{- 1} \frac{a + Δ}{\sqrt{{a}^{2} + {b}^{2}}} - {cos}^{- 1} \frac{b}{\sqrt{{a}^{2} + {b}^{2}}} < {θ}_{m ax} \leq {sin}^{- 1} \frac{a + Δ}{b} ,$$
and
wherein a maximum rotatable angle θₘₐₓ of the electronic component in a condition in which b>2a and Equation 1 is not satisfied or b≦2a satisfies the following Equation:
$${sin}^{- 1} \frac{a + Δ}{\sqrt{{a}^{2} + {b}^{2}}} - {cos}^{- 1} \frac{b}{\sqrt{{a}^{2} + {b}^{2}}} < {θ}_{m ax} \leq {cos}^{- 1} \frac{a}{a + Δ} , \\ wherein {sin}^{- 1} \frac{a + Δ}{b} and {cos}^{- 1} \frac{a}{a + Δ}$$
are a maximum rotatable angle θₘₐₓ_{_{—}}_{wmax} of the electronic component in the case in which
$${w}_{max} = \frac{ab}{a + Δ} ,$$
wₘₐₓ is a maximum connecting width of the connecting space for any Δ, and
$${sin}^{- 1} \frac{a + Δ}{\sqrt{{a}^{2} + {b}^{2}}} - {cos}^{- 1} \frac{b}{\sqrt{{a}^{2} + {b}^{2}}}$$
is a maximum rotatable angle in the independent cavity that does not have the connecting space and has the length of the short side, when viewed on the plane, corresponding to a+Δ.

6. The electronic component-embedded substrate according to claim 4, wherein the height h of the connecting space, when viewed on the plane, satisfies the following Equation: w tan θₘₐₓ≦h≦a+Δ in a condition in which the maximum rotatable angle θₘₐₓ of the electronic component accommodated in the embedding space satisfies the following Equation:
$${θ}_{max} \leq \frac{π}{4} ,$$
and
wherein the height h of the connecting space, when viewed on the plane, satisfies the following Equation:
$$\frac{w}{tan {θ}_{max}} \leq h \leq a + Δ$$
in a condition in which the maximum rotatable angle θₘₐₓ of the electronic component satisfies the following Equation:
$${θ}_{max} \geq \frac{π}{4} .$$

7. The electronic component-embedded substrate according to claim 3, wherein the height h of the connecting space, when viewed on the plane, satisfies the following Equation: h≦2(b sin θₘₐₓ+a cos θₘₐₓ−(a+Δ)).

8. The electronic component-embedded substrate according to claim 7, wherein
$$\frac{b}{2} \leq w , and Δ \leq ( \sqrt{2} - 1 ) a .$$

9. The electronic component-embedded substrate according to claim 2, wherein one end portion of at least one side forming the connecting width of the connecting space is connected to a short side of any one of first and second embedding spaces, so as to coincide therewith, and the other end portion thereof is bent and meets a long side of the other embedding space,
wherein w, which is a long width of the connecting space formed by a distal end of the other end portion, is larger than a short width of the connecting space formed by a bent point of the other end portion, and
wherein a maximum rotation angle is formed at a distal end of the other end portion at the time of maximum rotation of the electronic component accommodated in the embedding space.

10. An electronic component-embedded substrate, comprising:
a core substrate;
a cavity formed in the core substrate and comprising a first embedding space, which is one of two or more embedding spaces and is formed in a horizontal rectangular, when viewed on the plane, a connecting space, which is connected to a portion of a lower long side of the first embedding space, of which one side, when viewed on the plane, forming a connecting width coincides with one short side of the first embedding space and the other side (when viewed on the plane) meets the lower long side of the first embedding space, and a second embedding space which is formed in a horizontal rectangular shape, when viewed on the plane, and has the other short side coinciding with the other side, when viewed on the plane, of the connecting space and an upper long side meeting the one side, when viewed on the plane, of the connecting space;
two or more electronic components maximally rotatable at a point at which a side of the connecting space and a long side of the embedding space meet each other and separately accommodated in the embedding spaces of the cavity, respectively, so as not to contact each other at the time of being maximally rotated; and
upper and lower insulating layers covering the electronic components embedded in the cavity and having a plurality of vias formed therein so as to be electrically connected to the electronic components while penetrating through at least one thereof.

11. The electronic component-embedded substrate according to claim 10, wherein the connecting width w of the connecting space satisfies the following Equation:
$$a sin {θ}_{i} < w \leq \frac{ab}{a + Δ} ,$$
wherein a is a length of a short side (when viewed on the plane) of the electronic component, b is a length of a long side (when viewed on the plane) of the electronic component, Δ is a difference between a length of a short side of the embedding space and a length of the short side of the electronic component, and θₘₐₓ is a maximum rotatable angle in an independent cavity that does not have the connecting space and has a length of a short side, when viewed on the plane, corresponding to a+Δ.

12. The electronic component-embedded substrate according to claim 11, wherein A satisfies the following Equation: 0<Δ<b−a, and
wherein a height h of the connecting space, when viewed on the plane, which is a distance between the long side of the first embedding space and the long side of the second embedding space, satisfies the following Equation: h≦a+Δ.

13. The electronic component-embedded substrate according to claim 12, wherein the height h of the connecting space, when viewed on the plane, satisfies the following Equation: b sin θₘₐₓ+a cos θₘₐₓ−(a+Δ)<h,
wherein θₘₐₓ is a maximum rotatable angle of the electronic component accommodated in the embedding space.

14. The electronic component-embedded substrate according to claim 12, wherein
$$\frac{b}{2} \leq w , and Δ \leq ( \sqrt{2} - 1 ) a .$$

15. A manufacturing method of an electronic component-embedded substrate, the manufacturing method comprising:
forming a cavity, in a core substrate, configured that two or more embedding spaces having a rectangular shape, when viewed on the plane, are connected to each other by a connecting space so that neighboring long sides of first and second embedding spaces are partially connected to each other by the connecting space and one side, when viewed on the plane, forming a connecting width of the connecting space connecting the first and second embedding spaces coincides with one short side of the first embedding space and the other side, when viewed on the plane, coincides with the other short side of the second embedding space;
separately inserting two or more electronic components into the embedding spaces of the cavity, respectively; and
covering the cavity into which the electronic components are inserted with an insulating layer(s) and forming a plurality of vias electrically connected to the electronic components while penetrating through the insulating layer.

16. The manufacturing method of an electronic component-embedded substrate according to claim 15, wherein in the forming of the cavity, the cavity is formed so that the connecting width w of the connecting space satisfies the following Equation:
$$a sin {θ}_{i} < w \leq \frac{ab}{a + Δ} ,$$
wherein a is a length of a short side, when viewed on the plane, of the electronic component, b is a length of a long side, when viewed on the plane, of the electronic component, Δ is a difference between a length of a short side of the embedding space and a length of the short side of the electronic component, and θᵢ is a maximum rotatable angle in an independent cavity that does not have the connecting space and has a length of a short side, when viewed on the plane, corresponding to a+Δ.

17. The manufacturing method of an electronic component-embedded substrate according to claim 16, wherein in the forming of the cavity, the cavity is formed so that Δ satisfies the following Equation: 0<Δ<b−a, and a height h of the connecting space (when viewed on the plane), which is a distance between the long side of the first embedding space and the long side of the second embedding space, satisfies the following Equation: h≦a+Δ.

18. The manufacturing method of an electronic component-embedded substrate according to claim 17, wherein in the forming of the cavity, the cavity is formed so that a maximum rotatable angle θₘₐₓ of the electronic component accommodated in the embedding space in a condition of the following Equation 1:
$$0 < Δ < \sqrt{\frac{{b}^{2} + b \sqrt{{b}^{2} - 4 {a}^{2}}}{2}} - a$$
and b>2a satisfies the following Equation:
$${sin}^{- 1} \frac{a + Δ}{\sqrt{{a}^{2} + {b}^{2}}} - {cos}^{- 1} \frac{b}{\sqrt{{a}^{2} + {b}^{2}}} < {θ}_{max} \leq {sin}^{- 1} \frac{a + Δ}{b}$$
and a maximum rotatable angle θₘₐₓ of the electronic component in a condition in which Equation 1 is not satisfied or b≦2a satisfies the following Equation:
$${sin}^{- 1} \frac{a + Δ}{\sqrt{{a}^{2} + {b}^{2}}} - {cos}^{- 1} \frac{b}{\sqrt{{a}^{2} + {b}^{2}}} < {θ}_{max} \leq {cos}^{- 1} \frac{a}{a + Δ} , \\ wherein {sin}^{- 1} \frac{a + Δ}{b} and {cos}^{- 1} \frac{a}{a + Δ}$$
are a maximum rotatable angle θₘₐₓ_{_{—}}_{wmax} of the electronic component in the case in which
$${w}_{max} = \frac{ab}{a + Δ} ,$$
wₘₐₓ is a maximum connecting width of the connecting space for any Δ, and
$${sin}^{- 1} \frac{a + Δ}{\sqrt{{a}^{2} + {b}^{2}}} - {cos}^{- 1} \frac{b}{\sqrt{{a}^{2} + {b}^{2}}}$$
is a maximum rotatable angle in the independent cavity that does not have the connecting space and has the length of the short side, when viewed on the plane, corresponding to a+Δ.

19. The manufacturing method of an electronic component-embedded substrate according to claim 17, wherein in the forming of the cavity, the cavity is formed so that the height h of the connecting space (when viewed on the plane) satisfies the following Equation: b sin θₘₐₓ+a cos θₘₐₓ−(a+Δ)<h.

20. The manufacturing method of an electronic component-embedded substrate according to claim 17, wherein in the forming of the cavity, the cavity is formed so that
$$\frac{b}{2} \leq w , and Δ \leq ( \sqrt{2} - 1 ) a .$$
